(19) United States
(12) Patent Application Publication
(10) Pub. No.: US 2011/0180826 A1
(43) Pub. Date: Jul. 28, 2011

(54) PRINTING METHOD, METHOD FOR FORMING LIGHT EMITTING LAYER, METHOD FOR FORMING ORGANIC LIGHT EMITTING DEVICE, AND ORGANIC LIGHT EMITTING DEVICE

(75) Inventors: Shigeru MORITO, Matsudo-Shi (JP); Hiroki DOKE, Abiko-Shi (JP)

(73) Assignee: Dai Nippon Printing Co., Ltd., Shinjuku-Ku (JP)

(21) Appl. No.: 13/009,936

(22) Filed: Jan. 20, 2011

(30) Foreign Application Priority Data
Jan. 22, 2010 (JP) 2010-012358

(51) Int. Cl. H01L 51/52; B41F 33/00; H01L 51/56

(52) U.S. Cl. 257/89; 101/483; 438/46; 257/E51.022

(57) ABSTRACT

A printing machine includes: a frame; a flat anilox plate that is fixed to and located on the frame and has a plurality of cells on an upper surface of the anilox plate; an ink supplying tool that supplies the ink onto the upper surface of the anilox plate; a surface plate that is fixed to and located on the frame and on which the substrate is placed; and a printing cylinder that is arranged above the frame and is capable of moving above the frame. The printing cylinder has a flexographic plate. The flexographic plate contacts the upper surface of the anilox plate, receives the ink, and transfers the ink onto the substrate. The flexographic plate is made of an elastic material. The viscosity of the ink is in a range of 51 cP to 200 cP (ink temperature: 23° C.) at the shear rate of the ink is 100/second.

### CROSS REFERENCE TO RELATED APPLICATIONS

This application is based upon the prior Japanese Patent Application No. 2010-12358 filed on Jan. 22, 2010, the entire contents of which are incorporated herein by reference.

### BACKGROUND OF THE INVENTION

1. Field of the Invention

The present invention relates to a printing method for performing flexographic printing using a sheet-fed printing machine. The invention also relates to a method for forming, using the printing method, a light emitting layer in a light emitting element layer formed in an organic light emitting device. The invention also relates to a method for forming an organic light emitting device, which method includes a process of forming a light emitting layer using the printing method. The invention also relates to an organic light emitting device.

2. Description of the Related Art

Flexographic printing is one of examples of a method for more accurately printing a thin layer having a thickness of about 0.01 μm to 1 μm in a sheet-fed printing manner. The flexographic printing uses a printing cylinder that has a relief printing plate (flexographic plate) made of an elastic material. A flexible flexographic plate, made of an elastic material such as rubber or resin, is used in flexographic printing. The flexographic printing is performed with lower printing pressure than gravure printing and gravure offset printing. Thus, the flexographic printing is suitable for accurately printing a further fine layer on a layer less resistant to pressure.

For example, JP-A-2009-59496 describes a printing machine for manufacturing an organic electroluminescence panel, wherein the printing machine includes a surface plate on which a substrate is placed; a rotary printing cylinder that is arranged above the surface plate and has a flexographic plate; and an anilox roll arranged to face the printing cylinder. According to JP-A-2009-59496, the above-described printing machine prints ink for an organic light emitting layer on a pixel electrode that has low resistant to pressure, thereby forming an organic light emitting layer.

### SUMMARY OF THE INVENTION

Since the flexographic plate is made of a flexible elastic material such as rubber or resin, as described above, when the flexographic plate is pressed against the substrate so that ink is transferred to the substrate, the flexographic plate is elastically deformed toward the inside. Such a deformed flexographic plate is also subject to an elastic repulsion force that acts toward the outside (or toward the substrate). In this case, the flexographic plate may be bounced against the substrate due to the elastic repulsion force. As a result, shaking developed at the bouncing may produce a variation in the thickness of the ink printed on the substrate.

The present invention has been made in view of the aforementioned problems, and an object of the present invention is to provide a method for printing ink on a substrate with a uniform thickness.

According to the present invention, a method for performing flexographic printing using a sheet-fed printing machine, comprises the steps of:

placing a substrate on a surface plate that is fixed to and located on a frame;

supplying ink onto a flat anilox plate that is fixed to and located on the frame, the anilox plate having a plurality of cells formed on an upper surface of the anilox plate;

moving a printing cylinder in a rotating manner on the anilox plate so that a flexographic plate provided on the printing cylinder receives the ink from the cells of the anilox plate; and

moving the printing cylinder on the substrate located on the surface plate so that the received ink is transferred from the flexographic plate on the printing cylinder onto the substrate;

wherein the viscosity of the ink is in a range of 51 cP to 200 cP (ink temperature: 23° C.) at the shear rate of the ink is 100/second,

the flexographic plate on the printing cylinder is made of an elastic material, and

the printing cylinder rotates on the substrate at a rotational speed of 20 rpm or higher when the printing cylinder moves in a rotating manner on the substrate.

In the printing method according to the present invention, preferably, the ink may contain a solvent and a solid that is dissolved in the solvent, the surface tension of the solvent may be 37 dyne/cm or less, and the boiling point of the solvent may be in a range of 165° C. to 265° C.

In the printing method according to the present invention, it is preferable that the content of the solid in the ink be in a range of 1.5 to 4.0% by weight.

In the printing method according to the present invention, the anilox plate may have a plurality of cells arranged on the upper surface of the anilox plate in a matrix pattern, the plurality of cells being filled with the ink. In this case, it is preferable that the density of the cells be in a range of 100 lines per inch to 300 lines per inch in the anilox plate, the proportion of the total area of the cells to the area of a film-formed portion of the anilox plate be in a range of 55% to 95%, and the depths of the cells be in a range of 15 μm to 100 μm.

In the printing method according to the present invention, the anilox plate may have a plurality of cells arranged on the upper surface of the anilox plate in a striped pattern, the plurality of cells being filled with the ink. In this case, it is preferable that the density of the cells be in a range of 100 lines per inch to 300 lines per inch in the anilox plate, the proportion of the total area of the cells to the area of a film-formed portion of the anilox plate be in a range of 55% to 95%, the depths of the cells be in a range of 15 μm to 100 μm, and for each of the cells, the ratio of the maximum width of the cell in a printing direction to the maximum width of the cell in a direction perpendicular to the printing direction be 0.6 or larger.

In the printing method according to the present invention, the flexographic plate provided on the printing cylinder may be made of a water-developable resin material.

In the printing method according to the present invention, the flexographic plate provided on the printing cylinder may be made of a resin material that can be engraved with a laser.

In the printing method according to the present invention, the printing cylinder may include a metal roll and a flexographic plate that is fixed to an outer circumferential surface of the metal roll with an adhesive.

In the printing method according to the present invention, the printing cylinder may include a metal roll, a cylindrical plastic sleeve surrounding the metal roll, and a flexographic plate arranged on an outer circumferential surface of the plastic sleeve. In this case, the plastic sleeve may be arranged on the metal roll and fixed to the metal roll by an air clamping mechanism that is arranged in the metal roll. In addition, the plastic sleeve may be arranged on the metal roll and fixed to the metal roll by a suction mechanism that is arranged in the metal roll.

According to the present invention, a method for forming a light emitting layer in an organic light emitting device using the above-described printing method, the organic light emitting device including electrodes facing each other and a light emitting element layer, the light emitting element layer being arranged between the electrodes and having at least the light emitting layer, comprises the steps of:

filling the cells on the anilox plate with ink containing at least an organic light emitting material;

receiving the ink on the flexographic plate provided on the printing cylinder from the cells; and

transferring the ink on the printing cylinder onto the substrate;

wherein the viscosity of the ink is in a range of 51 cP to 200 cP (ink temperature: 23° C.) at the shear rate of the ink is 100/second,

the flexographic plate on the printing cylinder is made of an elastic material, and

the printing cylinder rotates on the substrate at a rotational speed of 20 rpm or higher when the printing cylinder moves in a rotating manner on the substrate.

According to the present invention, a method for forming an organic light emitting device which includes electrodes facing each other and a light emitting element layer, the light emitting element layer being arranged between the electrodes and having at least a light emitting layer, comprises the steps of:

preparing a substrate;

forming on the substrate a first electrode layer having a desired pattern;

forming, on the substrate, an insulating layer that has a plurality of openings formed such that desired portions of the first electrode layer are exposed upward;

forming a hole injection layer in the openings and on the insulating layer;

forming a light emitting layer above portions of the hole injection layer, the portions of the hole injection layer being located in the openings; and

forming a second electrode layer such that the second electrode layer is connected to portions of the light emitting layer, the portions of the light emitting layer being located in desired regions of the openings;

wherein the hole injection layer is formed in such a manner that the hole injection layer covers all the openings using a gravure printing method or a gravure offset printing method, and

wherein the light emitting layer is formed by the method according to the above-described light emitting layer forming method.

The organic light emitting device forming method according to the present invention may further include the step of forming a hole transport layer between the hole injection layer and the light emitting layer. In this case, the hole transport layer may be formed such that the hole transport layer covers all the openings using a gravure printing method or a gravure offset printing method.

According to the present invention, an organic light emitting device comprises:

a substrate;

a first electrode layer formed on the substrate, the first electrode layer having a desired pattern;

an insulating layer formed on the substrate, the insulating layer having a plurality of openings formed such that desired portions of the first electrode layer are exposed upward;

a light emitting element layer formed in the openings so as to cover the first electrode layer located in the openings, the light emitting element layer including at least a light emitting layer and a hole injection layer; and

a second electrode layer formed to be connected to portions of the light emitting layer in the light emitting element layer, the portions of the light emitting layer being located in desired regions of the openings;

wherein the light emitting layer provided in the light emitting element layer is formed by the above-described light emitting layer forming method.

In the organic light emitting device according to the present invention, the substrate may be a transparent substrate, and the first electrode layer may be a transparent electrode layer.

In the organic light emitting device according to the present invention, preferably the light emitting layer of the light emitting element layer may have a thickness of 70 nm or larger.

In the organic light emitting device according to the present invention, the light emitting element layer may include the hole injection layer, the light emitting layer and an electron injection layer, which are arranged in the openings provided in the insulating layer. In this case, the hole injection layer, the light emitting layer and the electron injection layer may be stacked in order of the hole injection layer, the light emitting layer and the electron injection layer.

In the organic light emitting device according to the present invention, the light emitting element layer may include the hole injection layer, a hole transport layer, the light emitting layer and an electron injection layer, which are arranged in the openings provided in the insulating layer. In this case, the hole injection layer, the hole transport layer, the light emitting layer and the electron injection layer may be stacked in order of the hole injection layer, the hole transport layer, the light emitting layer and the electron injection layer.

The organic light emitting device according to the present invention may be of passive matrix type.

The organic light emitting device according to the present invention may be of active matrix type.

The organic light emitting device according to the present invention may be an organic light emitting poster, the organic light emitting poster including the insulating layer that is provided with the openings having the maximum width of 10 mm or larger.

The organic light emitting device according to the present invention may include a color filter layer. In this case, the organic light emitting device according to the present invention may include a color conversion phosphor layer between the color filter layer and the first electrode layer.

In the organic light emitting device according to the present invention, the light emitting element layer may emit light of a desired color including white or emit light of a plurality of desired colors combined in a predetermined pattern.

In the organic light emitting device according to the present invention, the light emitting element layer may emit blue light, and the color conversion phosphor layer may include a green light conversion layer and a red light conversion layer. In this case, the green light conversion layer converts the blue light into green fluorescent light and emits the green fluorescent light, and the red light conversion layer converts the blue light into red fluorescent light and emits the red fluorescent light.

In the organic light emitting device according to the present invention, the hole injection layer and the light emitting layer may be formed such that after a film for the hole injection layer is formed, a film for the light emitting layer is formed within one minute after the coating of the film for the hole injection layer, and the hole injection layer and the light emitting layer are simultaneously dried at a temperature of 100° C. to 200° C.

According to the present invention, the method for performing flexographic printing using a sheet-fed printing machine includes the steps of: placing a substrate on a surface plate that is fixed to and located on a frame; supplying ink onto a flat anilox plate that is fixed to and located on the frame, the anilox plate having a plurality of cells formed on an upper surface of the anilox plate; moving a printing cylinder in a rotating manner on the anilox plate so that a flexographic plate provided on the printing cylinder receives the ink from the cells on the anilox plate; and moving the printing cylinder on the substrate located on the surface plate so that the received ink is transferred from the flexographic plate on the printing cylinder onto the substrate. In addition, the viscosity of the ink is in a range of 51 cP to 200 cP (ink temperature: 23° C.) at the shear rate of the ink is 100/second, and the flexographic plate on the printing cylinder is made of an elastic material. In this printing method, the printing cylinder rotates on the substrate at a rotational speed of 20 rpm or higher when the printing cylinder moves in a rotating manner on the substrate. Thus, even when an elastic repulsion force that acts toward an outside (or toward the substrate) is applied to a part of the flexographic plate, the part of the flexographic plate can move away from the substrate before the part of the flexographic plate is bounced against the substrate. This can prevent the thickness of the ink printed on the substrate from varying due to bouncing of the flexographic plate.

According to the present invention, the method for forming a light emitting layer for an organic light emitting device using the aforementioned printing method, includes the steps of: filling the cells on the anilox plate with ink for a light emitting layer containing at least an organic light emitting material; receiving the ink on the flexographic plate provided on the printing cylinder from the cells; and transferring the ink on the printing cylinder onto the substrate. In addition, the viscosity of the ink is in a range of 51 cP to 200 cP (ink temperature: 23° C.) at the shear rate of the ink is 100/second. The printing cylinder rotates on the substrate at a rotational speed of 20 rpm or higher when the printing cylinder moves in a rotating manner on the substrate. Thus, even when an elastic repulsion force that acts toward an outside (or toward the substrate) is applied to a part of the flexographic plate, the part of the flexographic plate can move away from the substrate before the part of the flexographic plate is bounced against the substrate. This can prevent the thickness of the ink printed on the substrate from varying due to bouncing of the flexographic plate.

According to the present invention, the method for forming an organic light emitting device includes the steps of: preparing a substrate; forming on the substrate a first electrode layer having a desired pattern; forming, on the substrate, an insulating layer that has a plurality of openings formed such that desired portions of the first electrode layer are exposed upward; forming a hole injection layer in the openings and on the insulating layer; forming a light emitting layer above portions of the hole injection layer, the portions of the hole injection layer being located in the openings; and forming a second electrode layer such that the second electrode layer is connected to portions of the light emitting layer, the portions of the light emitting layer being located in desired regions of the openings. In this case, the hole injection layer is formed so as to cover all the openings using a gravure printing method or a gravure offset printing method, and the light emitting layer is formed using the aforementioned light emitting layer forming method. Thus, it is possible to provide the organic light emitting device that includes a light emitting layer uniform in thickness.

According to the present invention, the organic light emitting device includes: a substrate; a first electrode layer formed on the substrate, the first electrode layer having a desired pattern; an insulating layer formed on the substrate, the insulating layer having a plurality of openings formed such that desired portions of the first electrode layer are exposed upward; a light emitting element layer formed in the openings so as to cover the first electrode layer located in the openings, the light emitting element layer including at least a light emitting layer and a hole injection layer; and a second electrode layer formed to be connected to portions of the light emitting layer in the light emitting element layer, the portions of the light emitting layer being located in desired regions of the openings. The light emitting layer in the light emitting element layer is formed by the aforementioned light emitting layer forming method. Thus, it is possible to provide the organic light emitting device that includes a light emitting layer uniform in thickness.

### BRIEF DESCRIPTION OF THE DRAWINGS

FIG. 1 is a side view of a printing machine according to an embodiment of the present invention.

FIG. 2 is a plan view of an anilox plate according to the embodiment of the present invention.

FIGS. 3A to 3C are plan views each showing a cell provided in the anilox plate according to the embodiment of the present invention and illustrating the ratio of the width b of the cell in a printing direction to the width a of the cell in a direction perpendicular to the printing direction.

FIG. 4A is a side view of a printing cylinder according to the embodiment of the present invention.

FIG. 4B is a view of the printing cylinder viewed from a direction indicated by an arrow IVb shown in FIG. 4A.

FIG. 5 is a partial cross-sectional perspective view of an organic light emitting device according to the embodiment of the present invention.

FIGS. 6A to 6E are diagrams showing a method for forming an organic light emitting device according to the embodiment of the present invention.

FIG. 7A is a side view of a printing machine according to a first comparative example.

FIG. 7B is a side view of a printing machine according to a second comparative example.

FIG. 8 is a diagram showing the state in which ink is printed on a substrate using a printing cylinder in the first or second comparative example.

FIG. 9 is a diagram showing an anilox plate according to a modified example of the embodiment of the present invention.

FIG. 10 is a diagram showing an anilox plate according to another modified example of the embodiment of the present invention.

FIG. 11 is a diagram showing an anilox plate according to another modified example of the embodiment of the present invention.

FIG. 12 is a diagram showing a printing cylinder according to another modified example of the embodiment of the present invention.

FIG. 13 is a plan view of an organic light emitting device according to another modified example of the embodiment of the present invention.

FIG. 14 is a diagram showing the relationship between a light emitting layer and openings provided in an insulating layer in the organic light emitting device shown in FIG. 13.

FIG. 15 is a perspective view of an organic light emitting device according to another embodiment of the present invention.

FIG. 16 is a cross-sectional view of the organic light emitting device shown in FIG. 15, taken along a line A-A.

FIG. 17 is a partial cross-sectional view of an organic light emitting device according to another embodiment of the present invention.

FIG. 18 is a partial cross-sectional view of an organic light emitting device according to another embodiment of the present invention.

FIG. 19A is a diagram showing the positions at which widths of portions of an object to be printed are measured in examples of the present invention.

FIG. 19B is a diagram showing a method for calculating a thickness variation rate of the object to be printed in the examples of the present invention.

### DETAILED DESCRIPTION OF THE PREFERRED EMBODIMENTS

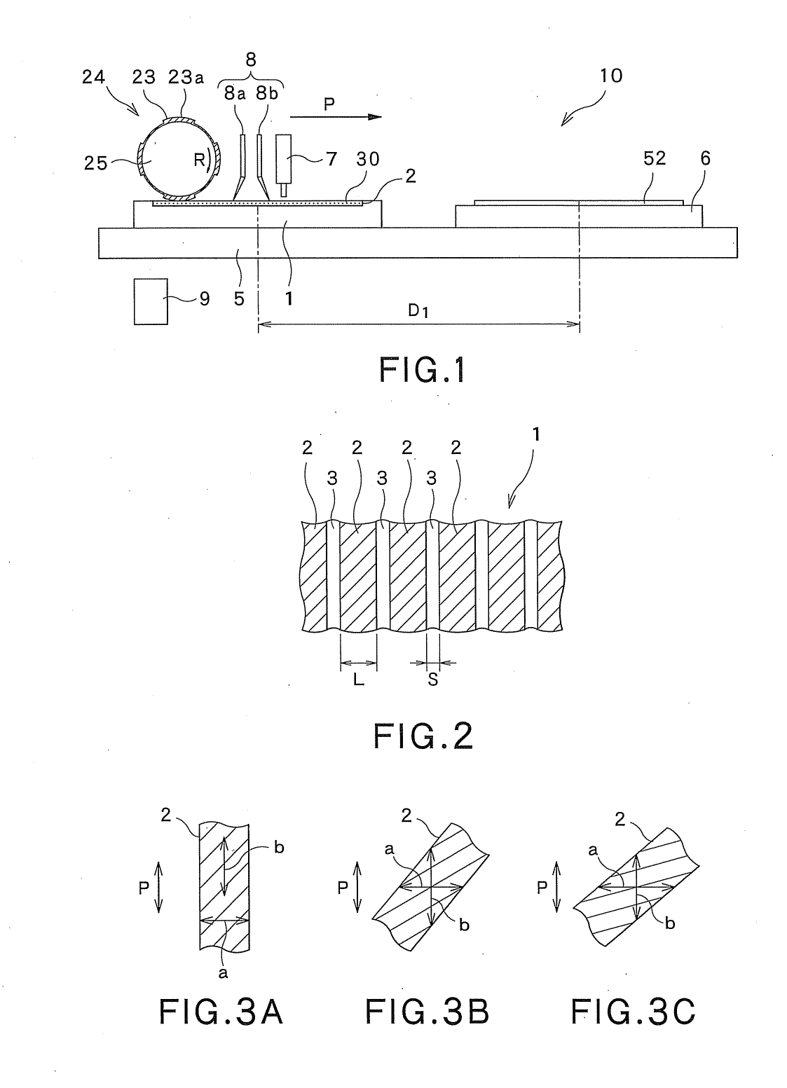

An embodiment of the present invention is described below with reference to FIGS. 1 to 5. First, a printing machine 10 is described with reference to FIG. 1.

### [Printing Machine]

As shown in FIG. 1, the printing machine 10 includes a frame 5, a flat anilox plate 1, a surface plate 6 and a printing cylinder 24. The anilox plate 1 is fixed to and located on the frame 5. The anilox plate 1 has a plurality of cells 2 formed on an upper surface of the anilox plate 1. The surface plate 6 is fixed to and located on the frame 5. A flat substrate 52 is placed on the surface plate 6. The printing cylinder 24 is arranged above the frame 5. The printing cylinder 24 is movable in a rotating manner on the frame 5 in a printing direction indicated by an arrow P. In addition, as shown in FIG. 1, the printing machine 10 includes an ink supplying tool 7 and a doctor system 8 that are located on the side (right side of FIG. 1) toward which the printing cylinder 24 moves. The ink supplying tool 7 supplies ink 30 onto an upper surface of the anilox plate 1. The doctor system 8 fills the cells 2 on the anilox plate 1 with the ink 30 supplied from the ink supplying tool 7. The doctor system 8 includes a first doctor 8a and a second doctor 8b. The first doctor 8a scrapes off the ink 30 deposited on the anilox plate 1 toward the right side of FIG. 1, while the second doctor 8b scrapes off the ink 30 deposited on the anilox plate 1 toward the left side of FIG. 1.

In the present embodiment, the printing machine 10 prints ink on substrates 52 one by one and is of a sheet-fed printing machine.

As shown in FIG. 1, the printing cylinder 24 includes a metal roll 25 and a flexographic plate 23. The metal roll 25 rotates in a direction indicated by an arrow R shown in FIG. 1. The flexographic plate 23 is fixed to an outer circumferential surface of the metal roll 25 with an adhesive and located on the outer circumferential surface of the metal roll 25. The flexographic plate 23 is made of an elastic material as will be described later. When projecting portions 23a (refer to FIG. 1) of the flexographic plate 23 contact the upper surface of the anilox plate 1, the ink 30 deposited in the cells 2 is received by the flexographic plate 23. After that, the ink 30 received by the flexographic plate 23 is transferred onto the substrate 52 placed on the surface plate 6. In this manner, the printing machine 10 according to the present invention performs flexographic printing using the flexographic plate 23.

The printing machine 10 according to the present embodiment uses the ink 30 having viscosity that is in a range of 51 cP to 200 cP (ink temperature: 23° C.) at the shear rate of the ink is 100/second. The viscosity of the ink 30 used by the printing machine 10 according to the present embodiment is lower than that of general ink. In order to transfer the ink 30 having low viscosity onto the substrate 52 with uniform thickness by means of a flexographic printing method, it is important to increase the rotational speed of the printing cylinder 24 as will be described later.

In a general printing machine that performs flexographic printing, an anilox plate (or an anilox roll) and a surface plate (or a backup roll) are capable of moving or rotating while a printing cylinder is capable of rotating. In the general printing machine, the printing cylinder is driven to rotate in synchronization with the movements or rotations of the anilox plate (or the anilox roll) and the surface plate (or the backup roll). Thus, when power used to rotationally drive the printing cylinder is increased or rapidly changed, the synchronization with the anilox plate (or the anilox roll) and the surface plate (or the backup roll) may not be maintained. Consequently, in the printing machine in which the printing cylinder is driven to rotate in synchronization with the movements or rotations of the anilox plate (or the anilox roll) and the surface plate (or the backup roll), it is difficult to increase the rotational speed of the printing cylinder or to rapidly change power that is used to rotationally drive the printing cylinder.

In the printing machine 10 according to the present embodiment, in contrast, the flat anilox plate 1 and the surface plate 6 on which the substrate 52 is placed are fixed to the frame 5 as described above. In addition, the printing cylinder 24 is arranged above the frame 5 and is capable of moving on the frame 5. The printing machine 10 performs flexographic printing by moving the printing cylinder 24 relative to the flat anilox plate 1 and the flat surface plate 6 while the flat anilox plate 1 and the flat surface plate 6 remain still as described above. In the printing machine 10, it is possible to increase or rapidly change the rotational speed of the printing cylinder 24 while the printing cylinder 24 is not misaligned and does not wobble.

In the printing machine 10 according to the present embodiment, the printing cylinder 24 is controlled by a control means 9 so as to move on the substrate 52 placed on the surface plate 6 at a rotational speed of 20 rpm or higher (or to rotate 20 or more times for one minute). Thus, it is possible to suppress a variation in the thickness of a layer made of the ink 30 transferred onto the substrate 52 as will be described later.

In the printing machine 10 according to the present embodiment, as shown in FIG. 1, the distance between the center of a pattern section (that is included in the cells 2 on the anilox plate 1 and from which the ink 30 is received by the flexographic plate 23 of the printing cylinder 24) of the anilox plate 1 in the printing direction P and the center of a pattern section (that is included in the substrate 52 and on which the ink 30 is printed by the printing machine 10) of the substrate 52 in the printing direction P is indicated by D₁. In the printing machine 10, the distance D₁ is set to n times (n is an integer of 1 or more) the length D₂ of the outer circumference of the printing cylinder 24. The length of the pattern section of the anilox plate 1 in the printing direction P is smaller than 0.9 times the length D₂ (0.9×D₂) of the outer circumference of the printing cylinder 24. Thus, when the printing cylinder 24 moves from the anilox plate 1 toward the substrate 52, the printing cylinder 24 idly rotates a distance of at least 0.1×D₂ or more in the printing direction P.

### [Anilox Plate]

The anilox plate 1 is described in detail below with reference to FIGS. 2 to 3C. FIG. 2 is a plan view of the anilox plate 1 according to the embodiment of the present invention. As shown in FIG. 2, the anilox plate 1 has the plurality of cells 2 formed on the upper surface of the anilox plate 1. The cells 2 are filled with the ink 30 supplied from the ink supplying tool 7. The cells 2 each have a stripe shape. In addition, non-cell portions 3 are present between pairs of the cells 2. The cells 2 and the non-cell portions 3 are arranged so that the proportion of the total area of all the cells 2 to all the area of a film-formed portion (constituted by the cells 2 and the non-cell portions 3) is in a range of 55% to 95%, preferably in a range of 70% to 95%. When the proportion of the total area of all the cells 2 to all the area of the film-formed portion is set as described above, the flexographic plate 23 can receive a sufficient amount of the ink 30. Thus, it is possible to set, to a desired thickness, the thickness of the ink 30 to be transferred onto the substrate 52. Therefore, it is possible to set, to a desired thickness, the thickness of the layer that is made of the ink 30 and formed on the substrate 52.

The width L of each of the cells 2 is in a range of 10 μm to 500 μm, preferably in a range of 30 μm to 300 μm. In addition, the width S of each of the non-cell portions 3 is in a range of 2 μm to 500 μm, preferably in a range of 5 μm to 200 μm.

Referring to FIGS. 3A to 3C, the ratio b/a of the width b of each of the cells 2 in the printing direction (indicated by the arrow P in the figures) to the width a of the cell 2 in a direction perpendicular to the printing direction is 0.6 or more, preferably 1 or more. The upper limit of the ratio b/a is not specified. As will be described later in examples, when the ratio b/a is less than 0.6, it is difficult to set the thickness of the layer that is made of the ink 30 and formed on the substrate 52 to a value of 70 nm or more.

The depth of each of the cells 2 is in a range of 15 μm to 100 μm, preferably in a range of 15 μm to 80 μm. The density of the cells 2 per inch in the direction perpendicular to the printing direction is in a range of 100 lines/inch to 300 lines/inch, preferably in a range of 120 lines/inch to 200 lines/inch. As will be described later, when the depth of each of the cells 2 is less than 15 μm, it is difficult to allow the layer that is made of the ink 30 and formed on the substrate 52 to have a large thickness. In contrast, when the depth of each of the cells 2 is equal to or larger than 100 μm, a variation in the thickness of the layer to be formed on the substrate 52 is large.

### [Printing Cylinder]

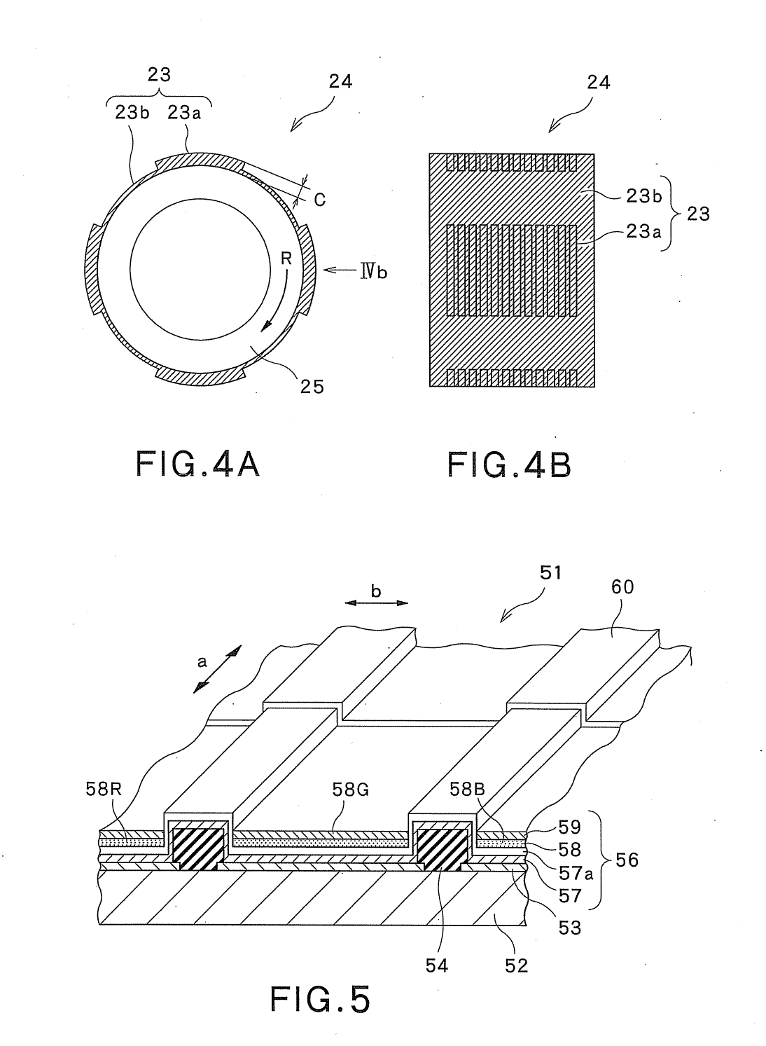

The printing cylinder 24 is described in detail below with reference to FIGS. 4A and 4B. As shown in FIG. 4A, the printing cylinder 24 includes the metal roll 25 and the flexographic plate 23. The metal roll 25 serves as a central shaft of the printing cylinder 24. The flexographic plate 23 is fixed to the outer circumferential surface of the metal roll 25 with the adhesive and located on the outer circumferential surface of the metal roll 25. The flexographic plate 23 is made of an elastic material as described above. As shown in FIGS. 4A and 4B, the flexographic plate 23 includes a plurality of projecting portions 23a and a recessed portion 23b. The projecting portions 23a are arranged in a striped pattern. Parts of the recessed portion 23b are present between each adjacent pair of the projecting portions 23a. The projecting portions 23a each extend in a rotational direction R of the printing cylinder 24. The heights c of the projecting portions 23a is in a range of 1 μm to 1000 μm, for example. The diameter of the printing cylinder 24 is 110 mm, for example.

A method for forming the flexographic plate 23 made of an elastic material is not limited. For example, the flexographic plate 23 can be formed by exposing a water-developable resin material with light, developing the exposed resin material with water, causing the developed resin material to be subjected to a film hardening process and performing baking on the resin material. As the water-developable resin material, polyvinyl alcohol or the like can be used.

In addition, the flexographic plate 23 may be formed by depositing a resin material on the outer circumference of the metal roll 25 using an adhesive and engraving the resin material with a laser. As the resin material that can be engraved with a laser, photosensitive resin that contains inorganic porous fine particles can be used. As the photosensitive resin, elastomer resin can be used, for example.

### [Ink]

The ink 30 that is used by the printing machine 10 according to the present embodiment is described in detail below. The ink 30 contains a solvent and a solid that is dissolved in the solvent. As the ink 30, the following ink is used: ink that has viscosity of 51 cP to 200 cP (ink temperature: 23° C.) at the shear rate of the ink is 100/second. The ink 30 that is used by the printing machine 10 according to the present embodiment has lower viscosity than general ink. Thus, the thickness of the layer that is made of the ink 30 easily varies compared with general ink. In order to suppress the variation, the rotational speed of the printing cylinder 24 is adjusted in the present embodiment as will be described later. It is, therefore, possible to suppress the variation in the thickness of the layer to be formed on the substrate 52.

When the viscosity of the ink 30 is less than 51 cP (ink temperature: 23° C.) under the condition that the shear rate of the ink 30 is 100/second, the ink may be dropped or it may be difficult to allow the layer to have a desired thickness. In contrast, when the viscosity of the ink 30 is larger than 200 cP (ink temperature: 23° C.) under the condition that the shear rate of the ink 30 is 100/second, unevenness of the ink received by the cells of the is large and whereby it is difficult to allow the layer made of the ink to have a uniform thickness. The aforementioned measurement of the viscosity is performed in a steady flow mode using a viscoelasticity measuring device MCR 301 made by Physica under the condition that the measurement temperature is set to 23° C. The ratio (V1/V2) of viscosity V1 of the ink 30 when the shear rate of the ink 30 is 100/second and the temperature of the ink 30 is 23° C. to viscosity V2 of the ink 30 when the shear rate of the ink 30 is 1000/second and the temperature of the ink 30 is 23° C. is preferably in a range of approximately 0.9 to 1.5. When the ratio V1/V2 is in the aforementioned range, the ink 30 exhibits Newtonian flow.

The surface tension of the solvent contained in the ink 30 used in the printing machine 10 is equal to or lower than 37 dyne/cm, preferably in a range of 30 dyne/cm to 35 dyne/cm. In addition, the boiling point of the solvent contained in the ink 30 is in a range of 165° C. to 265° C., preferably in a range of 180° C. to 210° C.

When the surface tension of the solvent contained in the ink 30 is higher than 37 dyne/cm, the ink receptivity of the printing cylinder 24 from the anilox plate 1 may be reduced. The reduction in the ink receptivity is not preferable. In addition, when the boiling point of the solvent contained in the ink 30 is lower than 165° C., the ink 30 transferred onto the substrate 52 from the printing cylinder 24 immediately becomes dry, and whereby an unnecessary streak may easily occur in the layer made of the ink 30. In addition, when the boiling point of the solvent contained in the ink 30 is higher than 265° C., it is difficult to dry the ink 30, and whereby a portion of the substrate 52 or the like, which is located in a dry zone, may be adversely affected by a long time drying, or the solvent may remain. These effects are not preferable. The surface tension of the solvent is measured using a surface tensiometer CBVP-Z made by Kyowa Interface Science Co., LTD. under the condition that the temperature of the solvent is 20° C.

### [Solid Contained in Ink]

The solvent and the solid that are contained in the ink 30 are arbitrarily selected on the basis of a layer to be formed on the substrate 52 by the printing machine 10. For example, when a light emitting layer 58 (provided in a light emitting element layer 56 that is included in an organic light emitting device 51) is formed by the printing machine 10 as will be described later, the following pigment based light emitting materials, the following metal complex based light emitting materials, and the following polymer based light emitting materials can be used as the solid that is contained in the ink 30 and used for the light emitting layer 58.

### (1) Pigment Based Light Emitting Materials

The following pigment based light emitting materials can be used as the solid contained in the ink 30: a cyclopentadiene derivative; a tetraphenyl butadiene derivative; a triphenylamine derivative; an oxadiazole derivative; a pyrazoloquinoline derivative; a distyrylbenzene derivative; a distyrylarylene derivative; a silole derivative; a thiophene ring compound; a pyridine ring compound; a perynone derivative; a perylene derivative; an oligothiophene derivative; a trifumanylamine derivative; an oxadiazole dimer; a pyrazoline dimer; and the like.

### (2) Metal Complex Based Light Emitting Materials

The following metal complex based light emitting materials can be used as the solid contained in the ink 30: an aluminum quinolinol complex; a benzoquinolinol beryllium complex; a benzoxazole zinc complex; a benzothiazole zinc complex; an azomethyl zinc complex; a porphyrin zinc complex; an europium complex; and the like. The metal complex based light emitting materials each contain central metal such as aluminum, zinc or beryllium or contain rear-earth metal such as terbium, europium or dysprosium and each have oxadiazole, thiadiazole, phenylpyridine, phenylbenzimidazole, quinoline or the like as a ligand.

### (3) Polymer Based Light Emitting Materials

The following polymer based light emitting materials can be used as the solid contained in the ink 30: a polyparaphenylene vinylene derivative; a polythiophene derivative; a polyparaphenylene derivative; a polysilane derivative; a polyacetylene derivative; a polyvinylcarbazole derivative; a polyfluorene derivative; and the like.

The content of the solid in the ink 30 used for the light emitting layer is preferably in a range of 1.5 to 4.0% by weight.

### [Solvent Contained in Ink]

In order for the printing machine 10 to form the light emitting layer 58 provided in the light emitting element layer 56 that is included in the organic light emitting device 51, a solvent that has a surface tension of 37 dyne/cm or less and a boiling point of 165° C. to 265° C. is used as the solvent contained in the ink 30. For example, cumene, anisole, n-propylbenzene, mesitylene, 1,2,4-trimethylbenzene, limonene, p-cymene, o-dichlorobenzene, butylbenzene, diethylbenzene, 2,3-dihydro-benzofurane, methyl benzoate, 1,2,3,4-tetramethylbenzene, amylbenzene, tetralin, ethyl benzoate, phenylhexane, cyclohexylbenzene, or butyl benzoate, can be used singly as the solvent for the solvent of the ink 30. In addition, when a mixed solvent is used as the solvent contained in the ink 30, the mixed solvent needs to have a surface tension (calculated on the basis of the mixing ratio) of 37 dyne/cm or less and a boiling point (calculated on the basis of the mixing ratio) of 165° C. to 265° C. For example, when a solvent 1 having a surface tension of A dyne/cm and a boiling point of B ° C. and a solvent 2 having a surface tension of C dyne/cm and a boiling point of D ° C. are mixed to form a mixed solvent and the ratio of the weight of the solvent 1 to the weight of the solvent 2 is 3:7, it is necessary that the surface tension [(A×3/10)+(C×7/10)] of the mixed solvent be equal to or less than 37 dyne/cm and the boiling point [(B×3/10)+(D×7/10)] of the mixed solvent be in a range of 165° C. to 265° C. In this case, the surface tensions of the solvents 1 and 2 that form the mixed solvent may be larger than 37 dyne/cm, and the boiling points of the solvents 1 and 2 may be out of the range of 165° C. to 265° C.

### [Organic Light Emitting Device]

Next, the organic light emitting device 51 that includes the light emitting layer 58 to be formed by the printing machine 10 according to the present embodiment is described with reference to FIG. 5. FIG. 5 is a partial cross-sectional perspective view of the organic light emitting device according to the present embodiment of the invention. As shown in FIG. 5, the organic light emitting device 51 includes the transparent substrate 52, a plurality of transparent electrode layers (first electrode layers) 53, an insulating layer 54, the light emitting element layer 56 and a plurality of electrode layers (second electrode layers) 60. The transparent electrode layers 53 are formed in a striped pattern. The insulating layer 54 has stripe-like openings 55. The electrode layers 60 are formed in a striped pattern. The plurality of transparent electrode layers 53 are arranged on the transparent substrate 52 and extend in a direction indicated by an arrow a shown in FIG. 5. The light emitting element layer 56 is arranged so that the transparent electrode layers 53 located in the openings 55 are covered with the light emitting element layer 56. The plurality of electrode layers 60 are arranged on the light emitting element layer 56 and extend in a direction indicated by an arrow b shown in FIG. 5. The plurality of electrode layers 60 extend in the direction perpendicular to the direction in which the transparent electrode layers 53 extend.

The openings 55 of the insulating layer 54 each have a stripe shape and extend in the direction indicated by the arrow a. The openings 55 are located on the transparent electrode layers 53 so that desired portions of the transparent electrode layers 53 are exposed upward.

The light emitting element layer 56 includes a hole injection layer 57, a hole transport layer 57a, the light emitting layer 58 and an electron injection layer 59. The hole injection layer 57 covers the transparent electrode layers 53 located in the openings 55. In the example shown in FIG. 5, the hole injection layer 57 and the hole transport layer 57a are formed solidly so that the hole injection layer 57 and the hole transport layer 57a cover the entire insulating layer 54 and all the openings 55. The light emitting layer 58 includes red light emitting layers 58R, green light emitting layers 58G and blue light emitting layers 58B. The red light emitting layers 58R, the green light emitting layers 58G and the blue light emitting layers 58B form a striped pattern. In other words, the red light emitting layer 58R, the green light emitting layer 58G and the blue light emitting layer 58B are repeatedly arranged in this order in the direction indicated by the arrow b. The light emitting layer 58 and the electron injection layer 59 may be formed on the insulating layer 54 located near edges of the openings 55. When the light emitting element layer 56 is formed on the insulating layer 54 located at edges of the openings 55, it is possible to reliably prevent the transparent electrode layers 53 and the electrode layers 60 from being short-circuited, while the light emitting element layer 56 is sandwiched between the transparent electrode layers 53 and the electrode layers 60. Thus, it is possible to improve reliability of the organic light emitting device 51.

The organic light emitting device 51 is of passive matrix type. That is to say, the organic light emitting device 51 has light emitting regions at which the transparent electrode layers 53 and the electrode layers 60 having the striped pattern cross each other. The light emitting layer 58 (including the red light emitting layers 58R, the green light emitting layers 58G and the blue light emitting layers 58B) is formed by the printing machine 10 according to the present embodiment. Thus, the thickness of the light emitting layer 58 can be set to 70 nm or more. Thus, the luminance of light emitted by the light emitting element layer 56 and the light emitting efficiency of the light emitting element layer 56 can be increased. Therefore, it is possible to display a high-quality image. The red light emitting layers 58R, the green light emitting layers 58G and the blue light emitting layers 58B are formed by sequentially transferring ink 30R (not shown) for the red light emitting layer, ink 30G (not shown) for the green light emitting layer and ink 30B (not shown) for the blue light emitting layer onto the substrate 52 by means of the printing machine 10 according to the present embodiment.

Next, the constituent members of the organic light emitting device 51 are described in detail.

### (Transparent Substrate)

First, the transparent substrate 52 is described in detail. When the organic light emitting device 51 is of a bottom emission type, the transparent substrate 52 is made of a transparent material and arranged so that the surface of the transparent substrate 52 is located on the side of an observer. For example, the transparent substrate 52 is made of a material that has transparency that makes light emitted by the light emitting layer 58 easily visible to the observer. When the light emitted by the light emitting layer 58 is extracted from the opposite direction (or when the organic light emitting device 51 is of a top emission type), a nontransparent substrate may be used instead of the transparent substrate 52.

As the transparent substrate 52 (or the nontransparent substrate used instead of the transparent substrate 52), a glass material, a resin material and a material containing a glass material and a resin material can be used. For example, a glass plate that includes a protective plastic film or a protective plastic layer can be used as the transparent substrate 52.

Examples of the above-described resin materials and protective plastics, which constitute the transparent substrate 52, include fluoroplastics, polyethylene, polypropylene, polyvinyl chloride, polyvinyl fluoride, polystyrene, ABS resins, polyamide, polyacetal, polyester, polycarbonate, modified polyphenylene ether, polysulfone, polyallylate, polyether imide, polyamide imide, polyimide, polyphenylene sulfide, liquid crystalline polyester, polyethylene terephthalate, polybutylene terephthalate, polyethylene naphthalate, polyoxymethylene, polyether sulfone, polyether ether ketone, polyacrylate, acrylonitrile-styrene resins, phenol resins, urea resins, melamine resins, unsaturated polyester resins, epoxy resins, polyurethane, silicone resins, and amorphous polyolefins. Resin materials other than the above-described ones can also be used if they are high-molecular-weight materials useful for organic light-emitting devices.

The thickness of the transparent substrate 52 is usually about 50 μm to 1.1 mm.

The material of the transparent substrate 52 depends on use of the organic light emitting device 51. It is more preferable that a material that has an excellent gas barrier property against water vapor, oxygen and the like be used as the material of the transparent substrate 52. In addition, a gas barrier layer against water vapor, oxygen and the like may be formed on the transparent substrate 52. In this case, the gas barrier layer can be formed on the transparent substrate 52 by depositing an inorganic oxide such as a silicon oxide, an aluminum oxide or a titanium oxide on the substrate 52 by means of a physical vapor deposition method such as a sputtering method or a vacuum vapor deposition method.

### (Transparent Electrode Layers)

Next, the transparent electrode layers 53 are described in detail. In the example shown in FIG. 5, the transparent electrode layers 53 are anode electrode layers. Since positive charges (holes) are injected in the light emitting layer 58, the transparent electrode layers 53 are adjacent to the hole injection layer 57. The transparent electrode layers 53 may be cathode electrode layers. When the transparent electrode layers 53 are cathode electrode layers, the hole injection layer 57 and the electron injection layer 59 are replaced with each other. The hole injection layer 57 and the electron injection layer 59 constitute parts of the light emitting element layer 56.

The transparent electrode layers 53 are not limited as long as the transparent electrode layers 53 are used in a general organic light emitting device. Metal, an alloy, a metal mixture or the like can be used as a material of the transparent electrode layers 53. For example, a thin film electrode material that contains an indium tin oxide (ITO), an indium oxide, an indium zinc oxide (IZO), a zinc oxide, a stannic oxide, or gold can be used as the material of the transparent electrode layers 53. Among those materials, the following materials are preferable: the ITO, the IZO, the indium oxide and gold, which each allow holes to be easily injected, have a large work function (of 4 eV or more), and are transparent or translucent materials.

The transparent electrode layers 53 preferably have sheet resistance of several hundred Ω/□ or less. The thicknesses of the transparent electrode layers 53 depend on the material of the transparent electrode layers 53. However, the thicknesses of the transparent electrode layers 53 can be set to approximately 0.005 μm to 1 μm.

The transparent electrode layers 53 extend from a peripheral terminal section to a pixel region at the central portion and have a desired pattern. The transparent electrode layers 53 that have the desired pattern are formed by a sputtering method, a vacuum vapor deposition method or the like using a metal mask. The transparent electrode layers 53 may be formed by depositing a material for the transparent electrode layer on all the regions of the substrate 52 and then etching the deposited material using a photosensitive resist as a mask.

The insulating layer 54 has the stripe-like openings 55 that are located on the transparent electrode layers 53. For example, the insulating layer 54 is formed by applying a photosensitive resin material on the entire upper surfaces of the transparent electrode layers 53 in such a manner that the transparent electrode layers 53 is covered with the photosensitive resin material, exposing the photosensitive resin material in a desired pattern, and developing the exposed photosensitive resin material. The insulating layer 54 may be made of a thermosetting resin material.

Light is not emitted from a region in which the insulating layer 54 is formed. The thickness of the insulating layer 54 is arbitrarily set on the basis of insulation resistance specific to the resin that constitutes the insulating layer 54. For example, the thickness of the insulating layer 54 is set to approximately 0.05 μm to 5.0 μm. In addition, the insulating layer 54 may be formed by mixing, with the aforementioned resin material, carbon black or light-shielding fine particles of one or more of titanium-based black pigments such as a titanium nitride, a titanium oxide and titanium oxynitride so that a black matrix is formed.

The shape of the insulating layer 54 is not limited to the aforementioned shape.

### (Light Emitting Element Layer)

Next, the light emitting element layer 56 is described in detail. In the example shown in FIG. 5, the light emitting element layer 56 has a structure in which the hole injection layer 57, the hole transport layer 57a, the light emitting layer 58 and the electron injection layer 59 are stacked from the side of the transparent electrode layers 53. However, the light emitting element layer 56 is not limited to this structure. The light emitting element layer 56 may be constituted by the hole injection layer 57, the light emitting layer 58 and the electron injection layer 59. In addition, the light emitting element layer 56 may be constituted by the hole injection layer 57 and the light emitting layer 58. Furthermore, the light emitting element layer 56 may be constituted, by the light emitting layer 58 and the electron injection layer 59. The light emitting element layer 56 may be constituted by the light emitting layer 58, the electron injection layer 59 and an electron transport layer that is located between the light emitting layer 58 and the electron injection layer 59.

In order to adjust the wavelength of light to be emitted and improve the efficiency of the emission, an appropriate material may be doped in each of the layers of the light emitting element layer 56.

The layers of the light emitting element layer 56 are described in detail below.

### Light Emitting Layer

The light emitting layer 58 provided in the light emitting element layer 56 is constituted by the red light emitting layer 58R, the green light emitting layer 58G and the blue light emitting layer 58B in the example shown in FIG. 5. However, the light emitting layer 58 is not limited to the aforementioned structure. A light emitting layer that emits light of a desired color (for example, yellow, aqua or orange) may be provided independently in the light emitting layer 58 according to use of the organic light emitting device. In addition, light emitting layers that emit light of desired colors other than red, green and blue may be provided in the light emitting layer 58.

As an organic light emitting material that is used for the light emitting layer 58, the materials described in the explanation of the solid included in the ink 30 can be used.

### Hole Injection Layer

The hole injection layer 57 provided in the light emitting element layer 56 is formed solidly so that the hole injection layer 57 covers the entire insulating layer 54 and all the openings 55 of the insulating layer 54. The hole injection layer 57 is formed by a gravure printing method (that will be described later) or a gravure offset printing method (that will be described later), for example. Ink that is used for the hole injection layer 57 in the gravure printing method or the gravure offset printing method is described below.

Examples of a solid (hole injection material) that is contained in the ink for the hole injection layer 57 are phenylamine series, starburst amine series, phthalocyanine series, oxides (such as a vanadium oxide, a molybdenum oxide, a ruthenium oxide and an aluminum oxide), amorphous carbon, polyaniline, a polythiophene derivative, a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, polysilane series, an aniline series copolymer, and dielectric oligomer such as thiophene oligomer.

Hole-injection materials may further include porphyrin compounds, aromatic tertiary amine compounds, and styrylamine compounds. Examples of the porphyrin compounds include porphine, 1,10,15,20-tetraphenyl-21H,23H-porphine copper (II), aluminum phthalocyanine chloride, and copper octamethylphthalocyanine. Examples of the aromatic tertiary amine compounds and the styrylamine compounds include N,N,N′,N′-tetraphenyl-4,4′-diaminophenyl, N,N-diphenyl-N,N′-bis(3-methylphenyl)[1,1′-biphenyl]-4,4′-diamine, 4-(di-p-tolylamino)-4′-[4(di-p-tolylamino)styryl]stilbene, 3-methoxy-4′-N,N-diphenylamino-stilbenzene, 4,4′-bis[N-(1-naphthyl)-N-phenylamino]biphenyl, and 4,4′,4″-tris[N-(3-methylphenyl)-N-phenylamino]triphenylamine.

The content of the above-described hole-injection material in the hole-injection-layer-forming ink may be made 0.3 to 10.0% by weight, for example.

An alcoholic solvent having a boiling point that falls in the above-described range (250° C. or less; for example, 60 to 250° C.) is used as the alcoholic solvent component of the solvent mixture for the hole-injection-layer-forming ink. Examples of such alcoholic solvents include methanol, ethanol, isopropyl alcohol, tert-butanol, n-propanol, sec-butanol, propylene glycol monomethyl ether, ethylene glycol monomethyl ether, propylene glycol monoethyl ether, ethylene glycol monoethyl ether, 2-(methoxymethoxy)ethanol, ethylene glycol monobutyl ether, ethylene glycol monoacetate, propylene glycol, dipropylene glycol monomethyl ether, diethylene glycol monomethyl ether, hexylene glycol, dipropylene glycol monoethyl ether, ethylene glycol, diethylene glycol monoethyl ether, 1,3-butylene glycol, 1-butoxyethoxy-2-propanol, diethylene glycol monobutyl ether, dipropylene glycol, 1,5-pentadiol, tripropylene glycol monomethyl ether, diethylene glycol, triethylene glycol monomethyl ether, and diethylene glycol monoacetate. These solvents may be used singly. In the case where two or more alcoholic solvents are used in combination, a solvent mixture whose boiling point, calculated from the mixture ratio, falls in the above-described range is used. For example, in the case of a 3:7 (weight basis) solvent mixture of a solvent 1 having a boiling point of A ° C. and a solvent 2 having a boiling point of B ° C., the boiling point of the solvent mixture calculated from the mixture ratio [(A×3/10)+(B×7/10)] has to fall in the above-described range (250° C. or less; for example, 60 to 250° C.). Individual alcoholic solvents constituting the solvent mixture may therefore have boiling points that are not in the above-described range.

### Hole Transport Layer

The hole transport layer 57a provided in the light emitting element layer 56 is formed solidly so that the light emitting element layer 56 covers the entire insulating layer 54 and all the openings 55 of the insulating layer 54. The transport layer 57a is formed by a gravure printing method or a gravure offset printing method, for example, in a similar manner to the hole injection layer 57. Examples of a solid (hole transport material) that is contained in the ink for the hole transport layer 57a formed by the gravure printing method or the gravure offset printing method are oxadiazole series, oxazole series, triazole series, thiazole series, triphenylmethane series, styryl series, pyrazoline series, hydrazone series, aromatic amine series, carbazole series, polyvinyl carbazole series, stilbene series, enamine series, azine series, triphenylamine series, butadiene series, polyaromatic compound series, and stilbene dimer.

Hole-transport materials also include p conjugated polymers such as polyacetylene, polydiacetylene, poly(p-phenylene), poly(p-phenylene sulfide), poly(p-phenylene oxide), poly(1,6-heptadiene), poly(p-phenylenevinylene), poly(2,5-thienylene), poly(2,5-pyrrole), poly(m-phenylene sulfide), and poly(4,4′-biphenylene).

Hole-transport materials also include high-molecular-weight charge-transfer complexes such as polystyrene.AgClO₄, polyvinyl-naphthalene.TCNE, polyvinylnaphthalene.P-CA, polyvinyinaphthalene.DDQ, polyvinylmesitylene.TCNE, polyna phthacetylene.TCNE, polyvinylanthracene.Br₂, polyvinylanthracene.I₂, polyvinylanthracene.TNB, polydimethylaminostyrene.CA, polyvinylimidazole.CQ, poly-p-phenylene.I₂, poly-4-vinylpyridine.I₂, poly-p-1-phenylene.I₂, and polyvinylpyridium.TCNQ.

Hole-transport materials also include low-molecular-weight charge-transfer complexes such as TCNQ-TTF, and polymeric metal complexes such as polycopper phthalocyanine.

Hole-transport materials having low ionization potential are preferred, and, specifically, butadiene compounds, enamine compounds, hydrazone compounds, and triphenylamine compounds are preferred.

### Electron Injection Layer

Examples of a material that is used for the electron injection layer 59 provided in the light emitting element layer 56 are calcium, barium, lithium aluminum, lithium fluoride, strontium, a magnesium oxide, magnesium fluoride, strontium fluoride, calcium fluoride, barium fluoride, an aluminum oxide, a strontium oxide, a calcium oxide, polymethylmethacrylate, sodium polystyrene sulfonate, a nitro-substituted fluorene derivative, an anthraquinodimethane derivative, a diphenylquinone derivative, a thiopyrandioxide derivative, a heterocyclic tetracarboxylic anhydride such as naphthaleneperylene, carbodiimide, a fluorenylidenmethane derivative, an anthraquinodimethane and anthrone derivative, an oxadiazole derivative, a thiazole derivative obtained by substituting oxygen atoms of an oxadiazole ring with sulfur atoms, a quinoxaline derivative containing a quinoxaline ring known as an electron withdrawing group, an 8-quinolinol derivative metal complex such as tris (8-quinolinol)aluminum, phthalocyanine, metal phthalocyanine, and a distyryl pyrazine derivative. The electron injection layer 59 made of any of the aforementioned materials is formed by forming a film by a vacuum deposition method or the like using a mask (that prevents a film from being formed on electrode terminals constituted by the peripheral transparent electrode layers 53) that has an opening portion corresponding to an image display region. The electron injection layer 59 may be formed by a printing method such as a screen printing method.

The thicknesses of the layers provided in the light emitting element layer 56 are not limited. The thicknesses of the layers provided in the light emitting element layer 56 can be set to a value of approximately 10 nm to 1000 nm. Examples of a material that is doped in each of the layers provided in the light emitting element layer 56 are a perylene derivative, a coumarin derivative, a rubrene derivative, a quinacridone derivative, a squalium derivative, a porphyrin derivative, a styryl series dye, a tetracene derivative, a pyrazoline derivative, decacyclene, and phenoxazone.

The hole injection layer 57 and the light emitting layer 58 may be formed such that after a film for the hole injection layer 57 is formed, a film for the light emitting layer 58 is formed within one minute after the coating of the film for the hole injection layer 57, and the layers 57 and 58 are simultaneously dried at a temperature of 100° C. to 200° C.

### (Electrode Layer)

Next, the electrode layer 60 is described in detail. The electrode layer 60 is a cathode layer in the example shown in FIG. 5. The electrode layer 60 is adjacent to the electron injection layer 59 since negative charges (electrons) are injected into the light emitting layer 58. The electrode layer 60 may be an anode layer. When the electrode layer 60 is an anode layer, the hole injection layer 57 and the electron injection layer 59, which are provided in the light emitting element layer 56, are replaced with each other.

A material of the electrode layer 60 is not limited as long as the electrode layer 60 is used in a general organic light emitting device. Examples of the material of the electrode layer 60 are thin film electrode materials (such as an indium tin oxide (ITO), an indium oxide, an indium zinc oxide (IZO), a zinc oxide, a stannic oxide, and gold), magnesium alloys (for example, MgAg and the like), aluminum, aluminum alloys (AlLi, AlCa, AlMg and the like), silver and the like. The material of the electrode layer 60 preferably has a small work function (of 4 eV or less) such as a magnesium alloy, aluminum, silver or the like, which each allow electrons to be easily injected. The electrode layer 60 preferably has sheet resistance of several hundred Ω/□ or less. In this case, the thickness of the electrode layer 60 can be set to a value of approximately 0.005 μm to 0.5 μm.

The electrode layer 60 is formed by forming any of the aforementioned electrode materials in a pattern using a mask by a sputtering method, a vacuum deposition method or the like.

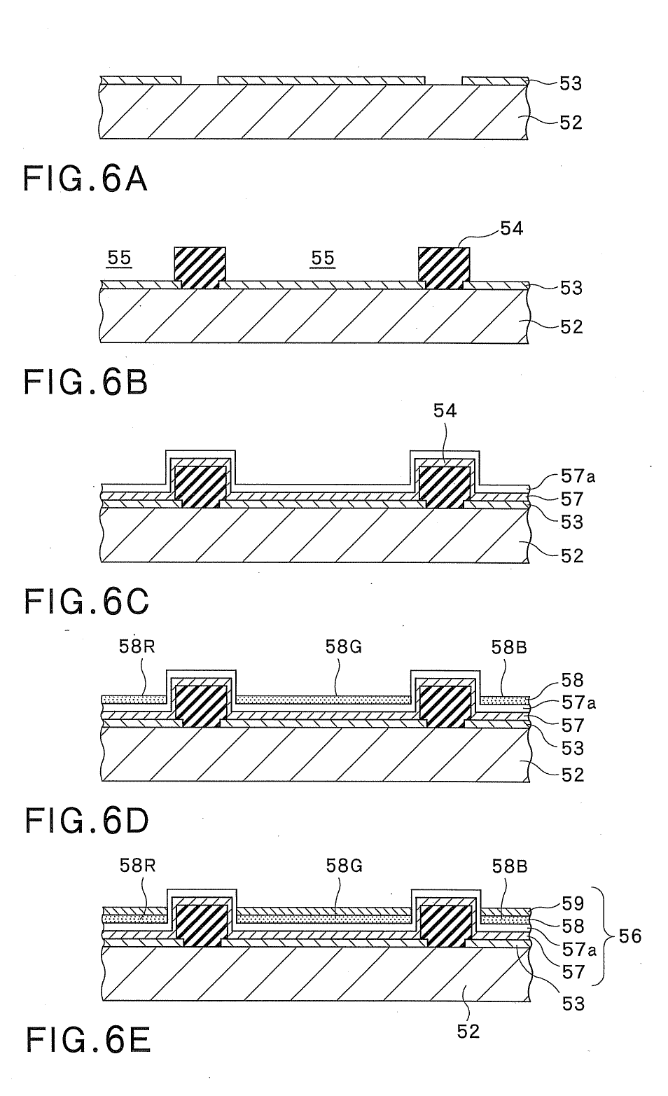

Next, effects of the aforementioned configuration according to the present embodiment are described. A method for forming the organic light emitting device 51 that has the light emitting layer 58 is described below with reference to FIG. 1 and FIGS. 6A to 6E.

As shown in FIG. 1, the transparent substrate 52 is placed on the surface plate 6 that is fixed to and located on the frame 5. Then, the transparent electrode layers 53 that have the desired pattern are formed on the transparent substrate 52 as shown in FIG. 6A. The method for forming the transparent electrode layers 53 is not limited. For example, the transparent electrode layers 53 that have the desired pattern are formed by a sputtering method using a metal mask, a vacuum deposition method or the like. The material for the transparent electrode layers 53 may be formed on the entire surface of the transparent substrate 52 and then etched using a photosensitive resist as a mask so that the transparent electrode layers 53 have the desired pattern.

Next, the insulating layer 54 that has the plurality of openings 55 is formed on the transparent substrate 52 as shown in FIG. 6B. In the openings 55, the desired portions of the transparent electrode layers 53 are exposed upward. In this case, the photosensitive resin material is coated on the entire upper surfaces of the transparent electrode layers 53 and covers the transparent electrode layers 53. After that, the coated photosensitive resin material is exposed with light so as to form a pattern. Then, the photosensitive resin material is developed. In this manner, the insulating layer 54 that has the plurality of openings 55 is formed.

After that, the hole injection layer 57 and the hole transport layer 57a are formed in the openings 55 and on the insulating layer 54 as shown in FIG. 6C. In this case, the hole injection layer 57 and the hole transport layer 57a are formed solidly by a gravure printing method or a gravure offset printing method. In general, printing pressure that is applied in the gravure printing method or the gravure offset printing method is larger than printing pressure that is applied in the flexographic printing method. Thus, a variation in the thickness of the hole injection layer 57 and the hole transport layer 57a formed by a gravure printing method or a gravure offset printing method is smaller than a variation in the thickness of a hole injection layer and the hole transport layer formed by a flexographic printing method.

As the gravure printing method or the gravure offset printing method, a gravure printing method using a gravure plate described in JP-A-2007-18948 or a gravure offset printing method using the gravure plate described in JP-A-2007-18948 may be used.

Next, the light emitting layer 58 is formed on parts of the hole transport layer 57a, which are located in the openings 55, as shown in FIG. 6D. In this case, the light emitting layer 58 is formed by the aforementioned printing machine 10.

A method for forming the light emitting layer 58 by means of the printing machine 10 is described in detail below. The ink 30 contains the organic light emitting material of the light emitting layer 58. First, the cells 2 on the anilox plate 1 are filled with the ink 30 by the doctor system 8. Next, the printing cylinder 24 moves on the anilox plate 1 in a rotating manner so that the flexographic plate 23 provided on the printing cylinder 24 receives the ink 30 from the cells 2 on the anilox plate 1. In this case, the rotational speed of the printing cylinder 24 is 20 rpm, for example. After that, the printing cylinder 24 moves toward the surface plate 6.

When the printing cylinder 24 moves from the anilox plate 1 toward the substrate 52, the printing cylinder 24 idly rotates a distance of at least 0.1×D₂ (D₂ is the length of the outer circumference of the printing cylinder 24) or more in the printing direction P. The control means 9 increases the rotational speed of the printing cylinder 24 to 20 rpm or higher during the idle rotation of the printing cylinder 24.

Next, the printing cylinder 24 rotates at a rotational speed of 20 rpm or higher on the transparent substrate 52 that is located on the surface plate 6. This rotation of the printing cylinder 24 causes the projecting portions 23a of the flexographic plate 23 to press the hole transport layer 57a formed above the transparent substrate 52 at a predetermined printing pressure. In this case, the ink 30 located on the projecting portions 23a is transferred onto the hole transport layer 57a that is located in the openings 55. After that, the transferred ink 30 is dried when necessary. In this manner, the light emitting layer 58 is formed on the hole transport layer 57a located in the openings 55.

After that, the electron injection layer 59 is formed on the light emitting layer 58 located in the openings 55 as shown in FIG. 6E. The method for forming the electron injection layer 59 is not limited. For example, the electron injection layer 59 is formed by forming a film by a vacuum deposition method or the like using a mask (that prevents a film from being formed on electrode terminals constituted by the peripheral transparent electrode layers 53) that has an opening portion corresponding to the image display region. In this manner, the light emitting element layer 56 that is constituted by the hole injection layer 57, the hole transport layer 57a, the light emitting layer 58 and the electron injection layer 59 is formed.

Lastly, the electrode layer 60 that has the predetermined pattern is formed. In this case, the electrode layer 60 is connected to portions of the light emitting element layer 56, which are located in desired regions of the openings 55. In this manner, the organic light emitting device 51 shown in FIG. 5 is formed.

In the present embodiment, in the process of forming the light emitting layer 58 by the printing machine 10, the viscosity of the ink 30 is in a range of 51 cP to 200 cP (ink temperature: 23° C.) at the shear rate of the ink is 100/second. As described above, the printing cylinder 24 is controlled by the control means 9 so as to rotate at a rotational speed of 20 rpm or higher when the printing cylinder moves in a rotating manner on the substrate. Thus, even when elastic repulsion forces that act toward the outside (or toward the transparent substrate 52) are applied to the elastically compressed projecting portions 23a, the ink 30 can be transferred from the projecting portions 23a onto the hole transport layer 57a located above the transparent substrate 52 before the projecting portions 23a are bounced against the transparent substrate 52. This prevents the thickness of the ink 30 (transferred onto the hole transport layer 57a located above the transparent substrate 52) from varying due to bouncing of the projecting portions 23a of the flexographic plate 23.

In this manner, the light emitting layer 58 that has a uniform thickness can be formed with high accuracy by the flexographic printing method in which printing pressure that is lower than printing pressure applied in the gravure printing method or the gravure offset printing method is applied to the hole transport layer 57a.

### Comparative Examples

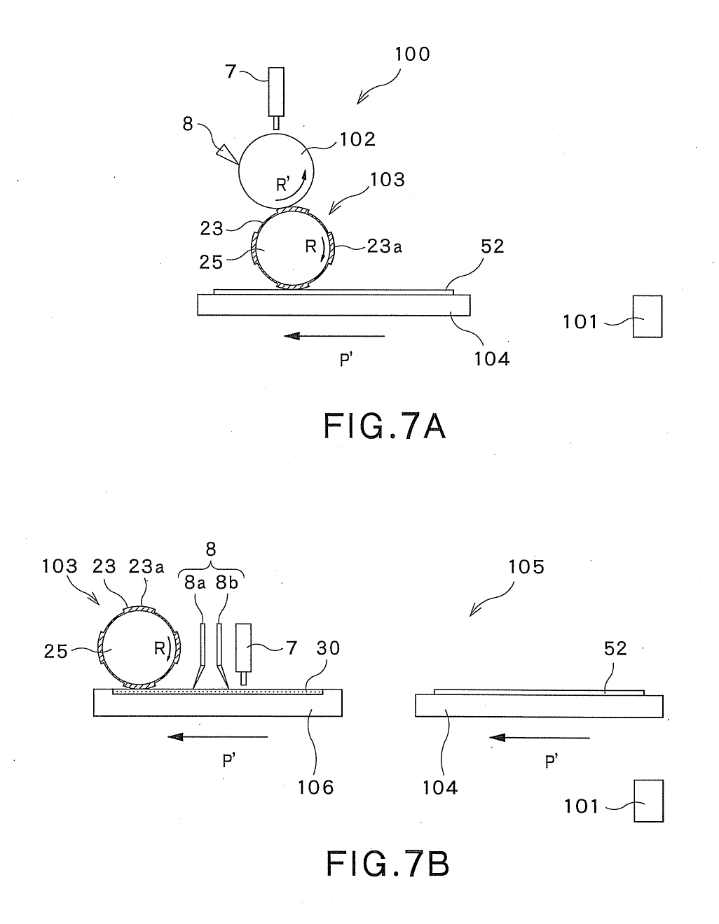

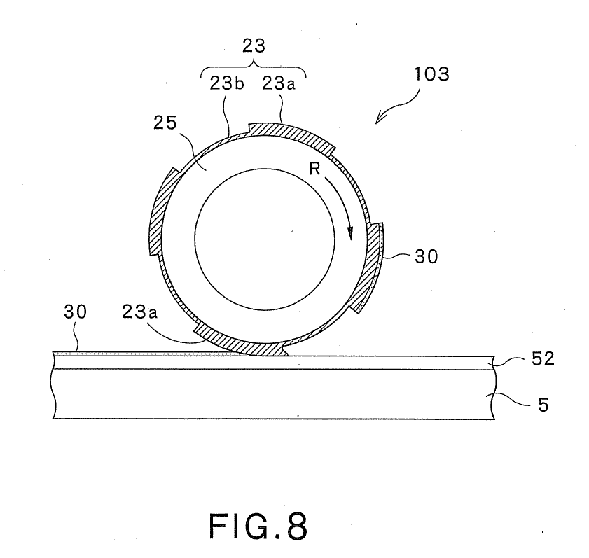

Effects of the present invention are described in comparison with first and second comparative examples with reference to FIGS. 7A, 7B and 8. FIG. 7A is a diagram showing a printing machine 100 according to the first comparative example, while FIG. 7B is a diagram showing a printing machine 105 according to the second comparative example. FIG. 8 is a diagram showing the state in which the ink 30 located on a printing cylinder 103 is transferred onto the transparent substrate 52 in the printing machine 100 according to the first comparative example or the printing machine 105 according to the second comparative example.

In the first and second comparative examples shown in FIGS. 7A, 7B and 8, parts that are the same as parts of the printing machine 10 according to the present embodiment shown in FIGS. 1 to 6E are indicated by the same reference numerals, and description thereof is omitted.

First, the printing machine 100 according to the first comparative example is described with reference to FIG. 7A. As shown in FIG. 7A, the ink 30 is supplied from the ink supplying tool 7 onto the printing cylinder 103 through an anilox roll 102 in the printing machine 100. In this case, the anilox roll 102 and the printing cylinder 103 rotate in a direction R′ and a direction R at a predetermined position, respectively, as shown in FIG. 7A. The printing cylinder 103 according to the first comparative example cannot move on a surface plate 104, unlike the printing cylinder 24 according to the present embodiment shown in FIGS. 1 to 6E. In order to transfer the ink 30 from the printing cylinder 103 onto the substrate 52, it is necessary that the surface plate 104 be moved in a direction P′ shown in FIG. 7A. The rotation of the anilox roll 102, the movement of the surface plate 104 and the rotation of the printing cylinder 103 are controlled by a control means 101 so as to be synchronized with each other.

As described above, in the printing machine 100 according to the first comparative example shown in FIG. 7A, the rotational speed of the printing cylinder 103 is controlled by the control means 101 so as to be synchronized with the rotation of the anilox roll 102 and the movement of the surface plate 104. Thus, the control of the rotational speed of the printing cylinder 103 provided in the printing machine 100 according to the first comparative example is more complicated than the control of the rotational speed of the printing cylinder 24 provided in the printing machine 10 that is used in the printing method according to the present invention. This is due to the fact that the rotation of the anilox roll 102 and the movement of the surface plate 104 are controlled so as to be synchronized with each other. Compared with the printing machine 10 that is used in the printing method according to the present invention, it is difficult to increase or rapidly change the rotational speed of the printing cylinder 103 in the printing machine 100 according to the first comparative example while the synchronization is maintained and misalignment does not occur. As a result, the rotational speed of the printing cylinder 103 is set to a value lower than 20 rpm in the printing machine 100 according to the first comparative example.

Next, the printing machine 105 according to the second comparative example is described with reference to FIG. 7B. The printing machine 105 shown in FIG. 7B has a feature of receiving the ink 30 from a flat anilox plate 106 by means of the printing cylinder 103. This feature is different from the printing machine 100 according to the first comparative example shown in FIG. 7A. Other configurations of the printing machine 105 are substantially the same as that of the printing machine 100 according to the first comparative example shown in FIG. 7A.

In the printing machine 105 according to the second comparative example shown in FIG. 7B, the printing cylinder 103 cannot move on the anilox plate 106 or the surface plate 104, like the printing machine 100 according to the first comparative example shown in FIG. 7A. In order to transfer the ink 30 from the anilox plate 106 onto the substrate 52, it is necessary to move the anilox plate 106 and the surface plate 104 in a direction P′ shown in FIG. 7B. The movement of the anilox plate 106, the movement of the surface plate 104 and the rotation of the printing cylinder 103 are controlled by the control means 101 so as to be synchronized with each other.

In the printing machine 105 according to the second comparative example shown in FIG. 7B, the rotational speed of the printing cylinder 103 is controlled by the control means 101 so as to be synchronized with the movement of the anilox plate 106 and the movement of the surface plate 104 as described above. Thus, the control of the rotational speed of the printing cylinder 103 provided in the printing machine 105 according to the second comparative example is more complicated than the control of the rotational speed of the printing cylinder 24 provided in the printing machine 10 that is used in the printing method according to the present invention. This is due to the fact that the movement of the anilox plate 106 and the movement of the surface plate 104 are controlled so as to be synchronized with each other. Compared with the printing machine 10 that is used in the printing method according to the present invention, it is difficult to increase or rapidly change the rotational speed of the printing cylinder 103 in the printing machine 105 according to the second comparative example while the synchronization is maintained and misalignment does not occur. As a result, the rotational speed of the printing cylinder 103 is set to a value lower than 20 rpm in the printing machine 105 according to the second comparative example.

FIG. 8 is a diagram showing the state in which the ink 30 located on the printing cylinder 103 is transferred onto the substrate 52 in the printing machine 100 according to the first comparative example or in the printing machine 105 according to the second comparative example. As shown in FIG. 8, the projecting portions 23a (of the flexographic plate 23 provided on the printing cylinder 103) that contact the substrate 52 is elastically compressed by printing pressure applied in order to transfer the ink 30. In this case, elastic repulsion forces that act toward the outside (or toward the substrate 52) are applied to the projecting portions 23a that are in contact with the substrate 52.

As described above, in the first or second comparative example, the printing cylinder 103 is controlled by the control means 101 so that the rotational speed of the printing cylinder 103 is set to a value lower than 20 rpm. Thus, the projecting portions 23a that contact the substrate 52 may be bounced against the substrate 52 due to the elastic repulsion forces applied to the projecting portions 23a before the projecting portions 23a moves away from the substrate 52. When the projecting portions 23a are bounced, the thickness of the ink 30 that is transferred from the flexographic plate 23 onto the substrate 52 may vary due to shaking caused by bouncing. Therefore, the thickness of the layer that is made of the ink 30 transferred onto the substrate 52 may vary.

In contrast, the printing machine 10 that is used in the printing method according to the present invention includes: the frame 5; the flat anilox plate 1 that is fixed to and located on the frame 5 and has the plurality of cells 2 formed on the upper surface of the anilox plate 1; the ink supplying tool 7 that supplies the ink 30 onto the upper surface of the anilox plate 1; the surface plate 6 that is fixed to and located on the frame 5 and on which the flat transparent substrate 52 is placed; and the printing cylinder 24 that is arranged above the frame 5 and is capable of moving above the frame 5. The printing cylinder 24 includes the flexographic plate 1. The flexographic plate 1 contacts the upper surface of the anilox plate 1 and receives the ink 30. After that, the flexographic plate 1 transfers the received ink 30 onto the substrate 52. The flexographic plate 1 is made of an elastic material. According to the present invention, the flat anilox plate 1 and the surface plate 6 are fixed to and located on an upper surface of the frame 5, and the printing cylinder 24 moves in a rotating manner on the anilox plate 1 and above the surface plate 6. According to the present invention, it is not necessary to synchronize a movement of the anilox plate 1 and a movement of the surface plate 6 when the printing cylinder 24 moves. Thus, the printing cylinder 24 is capable of rotating at a rotational speed of 20 rpm or higher on the transparent substrate 52 located on the surface plate 6 without misalignment. In the printing process, even when the elastic repulsion forces that act toward the outside are applied to the projecting portions 23a of the flexographic plate 23, the transfer of the ink 30 from the projecting portion 23a of the flexographic plate 23 onto the transparent substrate 52 can be completed before the projecting portions 23a of the flexographic plate 23 are bounced against the transparent substrate 52. It is, therefore, possible to prevent the thickness of the ink 30 transferred onto the transparent substrate 52 from varying due to bouncing of the flexographic plate 23.

### [Modified Examples of Anilox Plate]

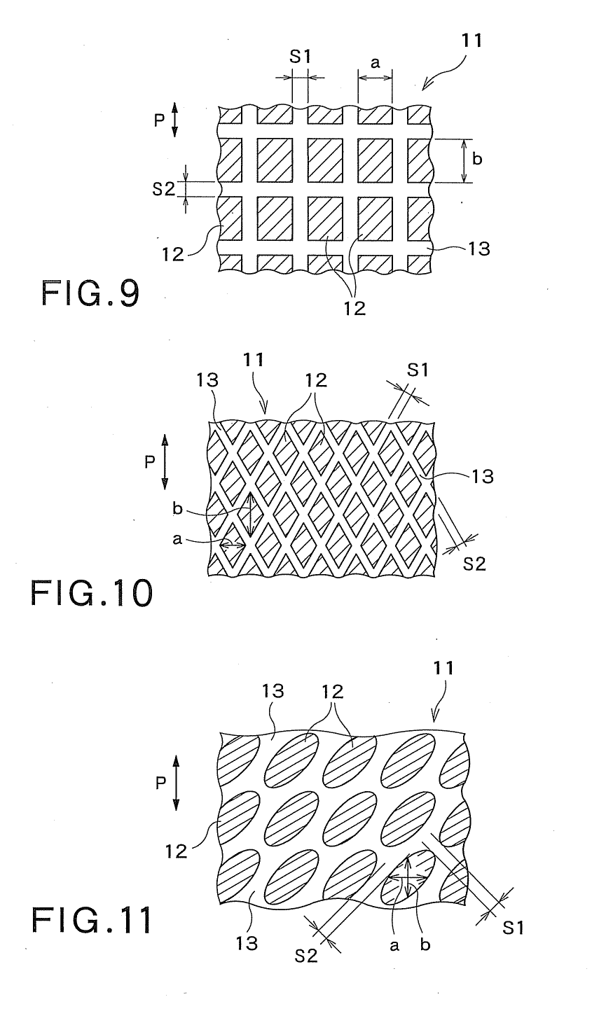

In the present embodiment, the anilox plate 1 has the plurality of cells 2 arranged on the upper surface of the anilox plate 1 in a striped pattern, the plurality of cells 2 being filled with the ink 30 supplied from the ink supplying tool 7. The anilox plate is not limited to the aforementioned configuration. As the anilox plate, any of anilox plates 11 shown in FIGS. 9 to 11 may be used. The anilox plates 11 each include cells 12 arranged on the upper surface of the anilox plate 11 in a matrix pattern and filled with the ink 30 supplied from the ink supplying tool 7.

FIG. 9 is a diagram showing the anilox plate 11 according to a modified example of the embodiment of the present invention. The anilox plate 11 shown in FIG. 9 has cells 12 (having a square shape in the example shown in FIG. 9) that are partitioned by a non-cell portion 13. Parts of the non-cell portion 13 shown in FIG. 9 are present between the cells 12. In addition, FIG. 10 is a diagram showing the anilox plate 11 according to another modified example of the embodiment of the present invention. The anilox plate 11 shown in FIG. 10 has cells 12 that are partitioned by a non-cell portion 13 and have a diamond shape. Parts of the non-cell portion 13 shown in FIG. 10 are present between the cells 12. FIG. 11 is a diagram showing the anilox plate 11 according to another modified example of the embodiment of the present invention. The anilox plate 11 shown in FIG. 11 has cells 12 that are partitioned by a non-cell portion 13 and have an elliptical shape. Parts of the non-cell portion 13 shown in FIG. 11 are present between the cells 12.

For each of the cells 12 on each of the anilox plates 11 shown in FIGS. 9 to 11, the ratio of the maximum width b of the cell 12 (indicated by hatched lines) in the printing direction (indicated by the arrow P in each of FIGS. 9 to 11) to the maximum width a of the cell in a direction perpendicular to the printing direction is 0.6 or more, preferably 1 or more. The upper limit of the ratio b/a is not specified. In addition, in each of the anilox plates 11 shown in FIGS. 9 to 11, the proportion of the total area of the cells to the area of a film-formed portion (constituted by the cells 12 and the non-cell portions 13) of the anilox plate 11 is in a range of 0.55 to 0.95, preferably in a range of 0.70 to 0.95. The widths S1 and S2 of the non-cell portions 13 shown in FIGS. 9 to 11 are in a range of 2 μm to 500 μm, preferably in a range of 10 μm to 200 μm. The depth of each of the cells 12 are in a range of 15 μm to 100 μm, preferably in a range of 15 μm to 80 μm.

When the ratio b/a is less than 0.6, it is difficult to allow the film to have a sufficient thickness. Thus, it is difficult to allow the light emitting layer 58 to have a thickness of 70 nm or more. Therefore, it is not preferable that the ratio b/a is less than 0.6. In addition, when the proportion of the total area of the cells to the area of the film-formed portion is less than 0.55, it is difficult to allow the film to have a sufficient thickness. Thus, it is not preferable that the proportion of the total area of the cells to the area of the film-formed portion is less than 0.55. In contrast, when the proportion of the total area of the cells to the area of the film-formed portion is larger than 0.95, a variation in the thickness of the film is large. Thus, it is not preferable that the proportion of the total area of the cells to the area of the film-formed portion is larger than 0.95. When the widths S1 and S2 of the non-cell portions 13 are less than 2 μm, it is difficult to form the cells 12 on the anilox plates 11. Thus, it is not preferable that the widths S1 and S2 of the non-cell portions 13 are less than 2 μm. In contrast, when the widths S1 and S2 of the non-cell portions 13 are larger than 500 μm, a variation in the thickness of the film is large and it is difficult to allow the film to have a sufficient thickness. Thus, it is not preferable that the widths S1 and S2 of the non-cell portions 13 are larger than 500 μm. When the depths of the cells 12 are less than 20 μm, it is difficult to allow the film to have a sufficient thickness. When the depths of the cells 12 are larger than 200 μm, the thickness of the film is not increased.

The shapes of the cells 12 on each of the anilox plates 11 are exemplified in the above description and are not limited to the aforementioned modified examples of the embodiment of the present invention.

### [Modified Examples of Printing Cylinder]

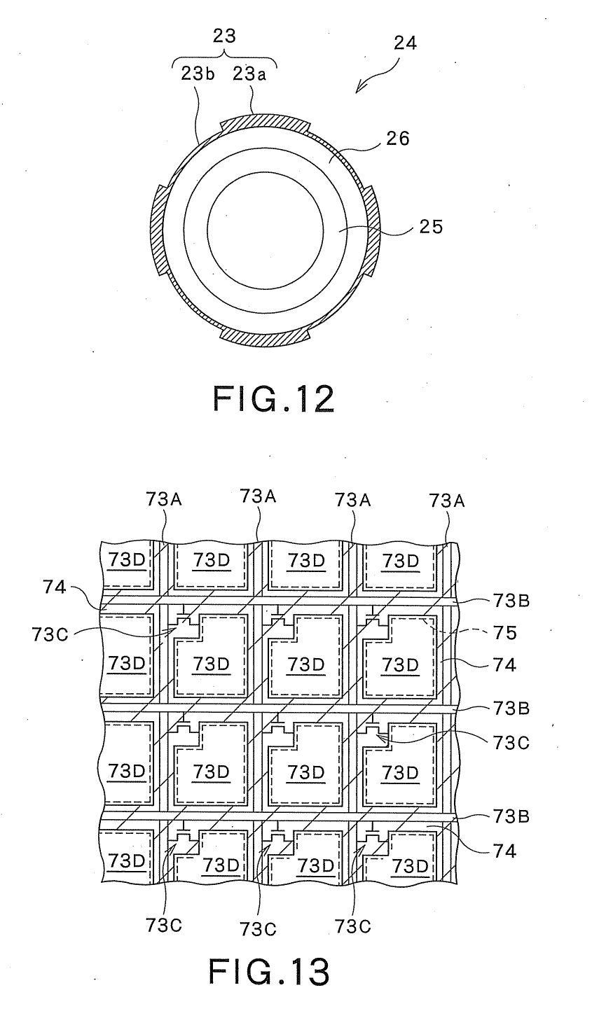

In the present embodiment, the printing cylinder 24 includes the metal roll 25 and the flexographic plate 23. The metal roll 25 serves as a central shaft of the printing cylinder 24. The flexographic plate 23 is fixed to the outer circumferential surface of the metal roll 25 with the adhesive and located on the outer circumferential surface of the metal roll 25. However, the printing cylinder 24 is not limited to the aforementioned configuration. As shown in FIG. 12, the printing cylinder 24 may include the metal roll 25, a cylindrical plastic sleeve 26 surrounding the metal roll 25, and the flexographic plate 23 arranged on an outer circumferential surface of the plastic sleeve 26. A method for fixing the plastic sleeve 26 to an upper surface of the metal roll 25 is not limited. For example, the plastic sleeve 26 may be arranged on the metal roll 25 and fixed to the metal roll 25 by an air clamping mechanism (not shown) that is arranged in the metal roll 25. In addition, the plastic sleeve 26 may be arranged on the metal roll 25 and fixed to the metal roll 25 by a suction mechanism (not shown) that is arranged in the metal roll 25.

### [Modified Example of Light Emitting Element Layer]

In the present embodiment, the hole injection layer 57 and the hole transport layer 57a, which are provided in the light emitting element layer 56, are formed solidly so that the hole injection layer 57 and the hole transport layer 57a cover the entire insulating layer 54 and the entire openings 55 provided in the insulating layer 54. However, the hole injection layer 57 and the hole transport layer 57a are not limited to this structure and may be formed only in the openings 55a.

### [Modified Example of Organic Light Emitting Device]

In the present embodiment, the organic light emitting device 51 is of passive matrix type and has the light emitting regions at which the transparent electrode layers 53 having the striped pattern and the electrode layer 60 cross each other. The organic light emitting device 51 is not limited to this and may be of active matrix type.

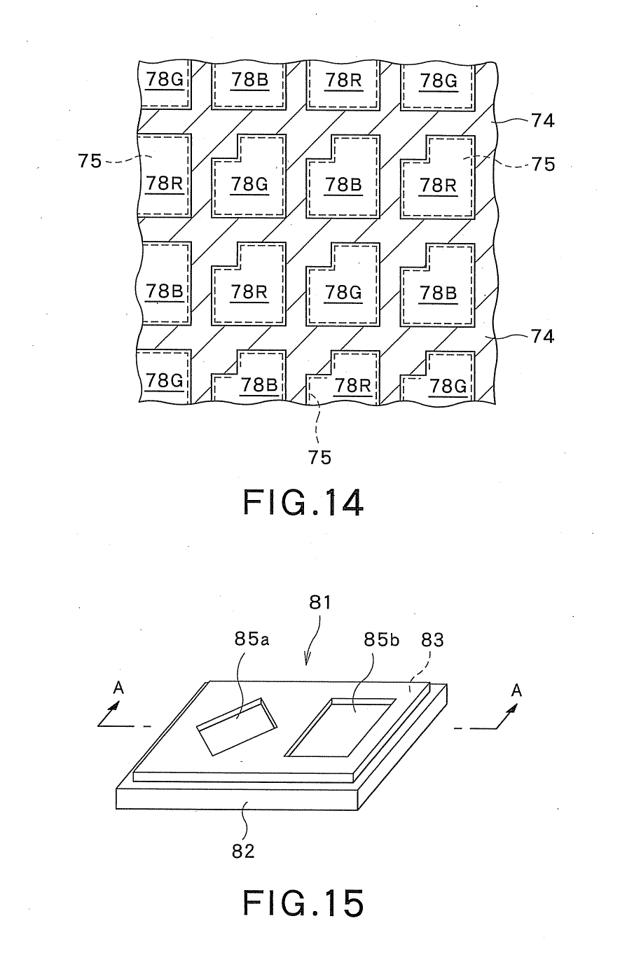

FIGS. 13 and 14 are diagrams showing examples of the active matrix type organic light emitting device according to a modified example of the present embodiment of the invention. FIG. 13 is a diagram showing an electrode wiring pattern 73 formed on a transparent substrate (not shown). The electrode wiring pattern 73 includes signal lines 73A, scanning lines 73B, thin film transistors (TFTs) 73C and transparent electrode (pixel electrode) layers 73D. An insulating layer 74 (indicated by hatched lines in FIG. 13) is formed on the electrode wiring pattern 73 and covers the electrode wiring pattern 73. The insulating layer 74 has openings 75 that are provided at positions corresponding to the transparent electrode layers 73D. A light emitting element layer (not shown) is formed so as to cover the transparent electrode layers 73D located in the openings 75. An electrode (common electrode) layer (not shown) is arranged on the light emitting element layer.

The light emitting element layer may be constituted by: a hole injection layer that covers the insulating layer 74 and the transparent electrode layers 73D located in the openings 75; a plurality of light emitting layers that are arranged in the openings 75 so as to cover the transparent electrode layers 73D (hole injection layer) located in the openings 75; and an electron injection layer that covers the hole injection layer and the plurality of light emitting layers. FIG. 14 is a diagram showing the relationship between the openings 75 provided in the insulating layer 74 and the light emitting layer. In the example shown in FIG. 14, the light emitting layer includes red light emitting layers 78R, green light emitting layers 78G and blue light emitting layers 78B. The red, green and blue light emitting layers 78R, 78G and 78B each have a desired pattern larger than the openings 75.

In the active matrix type organic light emitting device according to the present invention, the light emitting layer (including the red light emitting layers 78R, the green light emitting layers 78B and the blue light emitting layers 78B) is formed by the light emitting layer forming method according to the present invention. Thus, the light emitting layer (including the red light emitting layers 78R, the green light emitting layers 78B and the blue light emitting layers 78B) has a thickness of 70 nm or more. It is, therefore, possible to efficiently display a high-quality image with high-luminance light emitted by the light emitting element layer. When the light emitting element layer is formed on the insulating layer 74 located near edges of the openings 75, the transparent electrode layers 73D and an electrode layer (not shown) are not short-circuited with each other while the light emitting element layer is sandwiched between the transparent electrode layers 73D and the electrode layer (not shown). Thus, the reliability of the active matrix type organic light emitting device is improved.

The light emitting element layer may be constituted by the hole injection layer and the light emitting layer in a similar manner to the aforementioned embodiment. In addition, the light emitting element layer may be constituted by the light emitting layer and the electron injection layer. Furthermore, the light emitting element layer may be constituted by the hole injection layer, the light emitting layer and the hole transport layer that is located between the hole injection layer and the light emitting layer. Furthermore, the light emitting element layer may be constituted by the light emitting layer, the electron injection layer and the electron transport layer that is located between the light emitting layer and the electron injection layer.

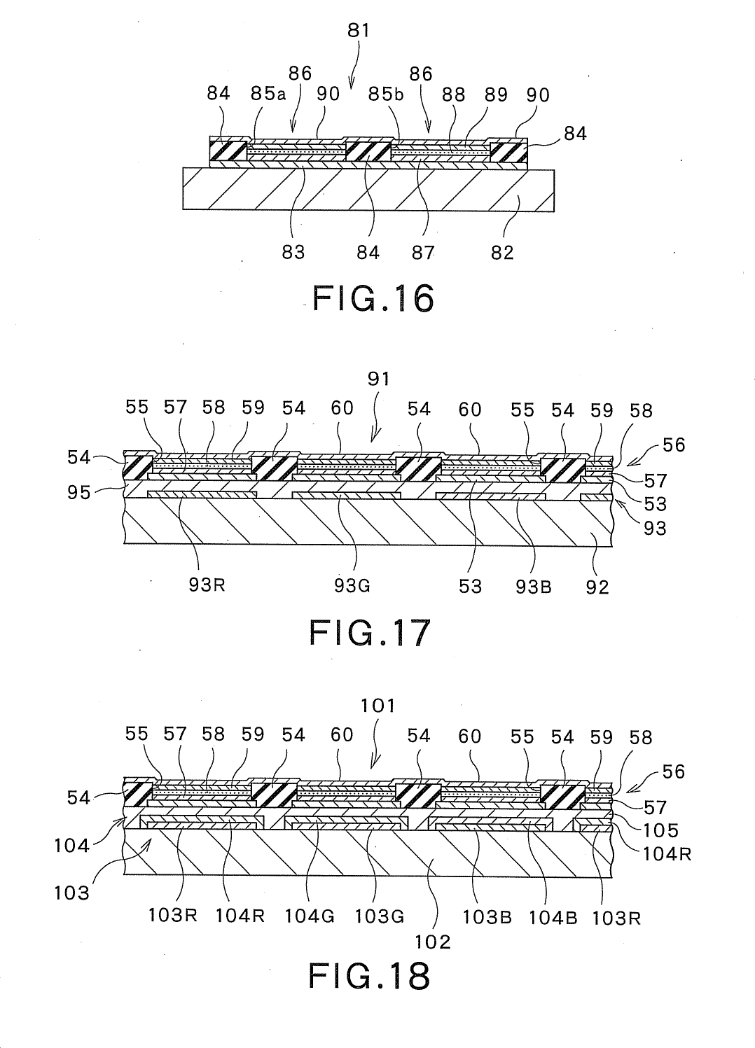

FIG. 15 is a partial perspective view of an organic light emitting device according to another embodiment of the present invention. FIG. 16 is a cross-sectional view of the organic light emitting device shown in FIG. 15, taken along line A-A. Referring to FIGS. 15 and 16, an organic light emitting device 81 includes a transparent substrate 82, a rectangular transparent electrode layer 83, an insulating layer 84, a light emitting element layer 86 and an electrode layer 90. The transparent electrode layer 83 is formed on the transparent substrate 82. The insulating layer 84 has a diamond-shaped opening 85a and a rectangular opening 85b. The light emitting element layer 86 covers portions of the transparent electrode layer 83, which are located in the openings 85a and 85b. The electrode layer 90 covers the light emitting element layer 86.

The light emitting element layer 86 is constituted by a hole injection layer 87, a light emitting layer 88 and an electron injection layer 89, which are stacked. The light emitting layer 86 may be formed on the insulating layer 84 located near edges of the openings 85a and 85b.

The organic light emitting device 81 is an area color display device that has display regions at the openings 85a and 85b. In this case, when the maximum widths of the openings 85a and 85b are set to 10 mm or more, the organic light emitting device 81 can be used as an organic light emitting poster. The light emitting layer 88 that constitutes a part of the organic light emitting device 81 is formed by the light emitting layer forming method according to the present invention. Thus, the thickness of the light emitting layer 88 is set to 70 nm or more. Therefore, the luminance of light emitted by the light emitting element layer 86 is high, and the efficiency of emitting light from the light emitting element layer 86 is high. It is, therefore, possible to display a high-quality image. When the light emitting element layer 86 is formed on the insulating layer 84 located near the edges of the openings 85a and 85b, the transparent electrode layer 83 and the electrode layer 90 are not short-circuited with each other while the light emitting element layer 86 is sandwiched between the transparent electrode layer 83 and the electrode layer 90. Thus, the reliability of the organic light emitting device 81 is improved.

The light emitting layer 88 may be arranged so that the color of light that is emitted by the light emitting layer located in the opening 85a is different from the color of light that is emitted by the light emitting layer located in the opening 85b. Portions of the electrode layer 90, which are formed at positions that correspond to the openings 85a and 85b, respectively, may be electrically independent from each other, and parts of the light emitting layer 88 may independently emit light.

In a similar manner to the aforementioned embodiments, the light emitting element layer 86 may be constituted by the hole injection layer and the light emitting layer. In addition, the light emitting element layer 86 may be constituted by the light emitting layer and the electron injection layer. Furthermore, the light emitting element layer 86 may be constituted by the hole injection layer, the light emitting layer and a hole transport layer that is located between the hole injection layer and the light emitting layer. Furthermore, the light emitting element layer 86 may be constituted by the light emitting layer, the electron injection layer and an electron transport layer that is located between the light emitting layer and the electron injection layer.

FIG. 17 is a partial perspective view of an organic light emitting device according to another embodiment of the present invention. An organic light emitting device 91 shown in FIG. 17 includes a transparent substrate 92, a color filter layer 93, a transparent flattening layer 95, the plurality of transparent electrode layer 53, the insulating layer 54, the light emitting element layer 56, and the plurality of electrode layers 60. The color filter layer 93 is formed on the transparent substrate 92. The color filter layer 93 includes a red-colored layer 93R, a green-colored layer 93G and a blue-colored layer 93B and has a striped pattern. The transparent electrode layers 53 have a striped pattern. The electrode layers 60 have a striped pattern. The transparent flattening layer 95 covers the color filter layer 93. The plurality of transparent electrode layers 53 are formed on the transparent flattening layer 95 in a similar manner to the organic light emitting device 51 according to each of the aforementioned embodiments. The insulating layer 54 has openings 55 that have a striped pattern and are located on the transparent electrode layers 53. The light emitting element layer 56 covers the transparent electrode layers 53 located in the openings 55. The electrode layers 60 are located on the light emitting element layer 56 and extend in a direction perpendicular to a direction in which the transparent electrode layers 53 extend.

The transparent electrode layers 53 that have the striped pattern are located on the red-colored layer 93R, the green-colored layer 93G and the blue-colored layer 93B. The red-colored layer 93R, the green-colored layer 93G and the blue-colored layer 93B have a striped pattern. In addition, the light emitting element layer 56 is constituted by the hole injection layer 57, the plurality of light emitting layers 58 and the electron injection layer 59. The hole injection layer 57 covers the transparent electrode layers 53 located in the openings 55. The light emitting layers 58 are located in the openings 55 so as to cover the transparent electrode layers 53 (the hole injection layer 57) located in the openings 55. The electron injection layer 59 covers the hole injection layer 57 and the light emitting layers 58. In the example shown in FIG. 17, the light emitting layers 58 are white light emitting layers that have a striped pattern. The light emitting element layer 56 may be formed on the insulating layer 54 located near edges of the openings 55.

The organic light emitting device 91 includes the color filter layer 93 and the transparent flattening layer 95. The organic light emitting device 91 is similar to the aforementioned organic light emitting device 51 except that the light emitting layers 58 are white light emitting layers. Thus, the same members are indicated by the same reference numerals, and description thereof is omitted. In a similar manner to the aforementioned embodiments, the light emitting element layer 56 may be constituted by the hole injection layer and the light emitting layers. In addition, the light emitting element layer 56 may be constituted by the light emitting layers and the electron injection layer. Furthermore, the light emitting element layer 56 may be constituted by the hole injection layer, the light emitting layers and a hole transport layer that is located between the hole injection layer and the light emitting layers. Furthermore, the light emitting element layer 56 may be constituted by the light emitting layers, the electron injection layer, and an electron transport layer that is located between the light emitting layers and the electron injection layer.

The color filter layer 93 corrects the color of light emitted by the light emitting element layer 56 or increases the purity of the color of the light emitted by the light emitting element layer 56. Materials of the red-colored, green-colored and blue-colored layers 93R, 93G and 93B that constitute the color filter layer 93 can be selected on the basis of light emitting characteristics of the light emitting element layer 56. Each of the red-colored, green-colored and blue-colored layers 93R, 93G and 93B can be made of a pigment, a pigment dispersant, binder resin, or a pigment dispersion composition containing a reactive compound and a solvent. The thickness of the color filter layer 93 can be set on the basis of the material of each of the colored layers, light emitting characteristics of the light emitting element layer 56 or the like. For example, the thickness of the color filter layer 93 can be set to a range of approximately 1 μm to 3 μm.

In addition, when a step (protruding and recessed portions) is present in an upper surface of the color filter layer 93 or an upper surface of the structure located under the color filter layer 93, the transparent flattening layer 95 eliminates the step and flattens out the upper surfaces so as to prevent an irregularity of the thickness of the light emitting element layer 56. The transparent flattening layer 95 can be made of transparent resin (having a visible light transmittance of 50% or more). Specifically, as a material of the transparent flattening layer 95, photo-setting resin containing an acrylate-based or methacrylate-based reactive vinyl group and thermosetting resin can be used. Examples of the transparent resin of the transparent flattening layer 95 are polymethylmethacrylate, polyacrylate, polycarbonate, polyvinylalcohol, polyvinylpyrrolidone, hydroxyethyl cellulose, carboxymethyl cellulose, polyvinylidene chloride resin, melamine resin, phenolic resin, alkyd resin, epoxy resin, polyurethane resin, polyester resin, maleic acid resin and polyamide resin.

The thickness of the transparent flattening layer 95 is set, on the basis of a material used for the transparent flattening layer 95, to a range that allows the flattening effect to be obtained. For example, the thickness of the transparent flattening layer 95 is set to a range of 1 μm to 5 μm.

FIG. 18 is a partial cross-sectional view of an organic light emitting device according to another embodiment of the present invention. The organic light emitting device shown in FIG. 18 includes a transparent substrate 102, a color filter layer 103, and a color conversion phosphor layer 104. The color filter layer 103 is formed on the transparent substrate 102 and constituted by a red-colored layer 103R, a green-colored layer 103G and a blue-colored layer 103B. The red-colored layer 103R, the green-colored layer 103G and the blue-colored layer 103B have a striped pattern. The color conversion phosphor layer 104 is constituted by a red light conversion phosphor layer 104R, a green light conversion phosphor layer 104G and a blue light dummy layer 104B. The red light conversion phosphor layer 104R, the green light conversion phosphor layer 104G and the blue light dummy layer 104B have a striped pattern. The red light conversion phosphor layer 104R converts blue light into red fluorescent light. The green light conversion phosphor layer 104G converts blue light into green fluorescent light. Blue light passes through the blue light dummy layer 104B without change. The color conversion phosphor layer 104 covers the red-colored layer 103R, the green-colored layer 103G and the blue-colored layer 103B. The organic light emitting device 101 shown in FIG. 18 further includes a transparent flattening layer 105, the plurality of transparent electrode layers 53, the insulating layer 54, the light emitting element layer 56 and the plurality of electrode layers 60. The transparent flattening layer 105 covers the color filter layer 103 and the color conversion phosphor layer 104. The transparent electrode layers 53 are formed on the transparent flattening layer 105 and have a striped pattern. The electrode layers 60 have a striped pattern. The transparent electrode layers 53 are formed in a similar manner to the electrode layers 53 included in the organic light emitting device 51 according to each of the aforementioned embodiments. The insulating layer 54 is arranged so that stripe-like openings 55 are positioned on the transparent electrode layers 53. The light emitting element layer 56 covers the transparent electrode layers 53 located in the openings 55. The electrode layers 60 are located on the light emitting element layer 56 and extend in a direction perpendicular to a direction in which the transparent electrode layers 53 extend.

The transparent electrode layers 53 having the striped pattern are located on the red light conversion phosphor layer 104R, the green light conversion phosphor layer 104G and the blue light dummy layer 104B. The red light conversion phosphor layer 104R, the green light conversion phosphor layer 104G and the blue light dummy layer 104B have the striped pattern. The light emitting element layer 56 is constituted by the hole injection layer 57, the light emitting layer 58 and the electron injection layer 59, which cover the transparent electrode layers 53 located in the openings 55. The light emitting layer 58 is a blue light emitting layer having a striped pattern. The light emitting element layer 56 may be formed on the insulating layer 54 located near edges of the openings 55.

The organic light emitting device 101 is similar to the organic light emitting device 51 except that the organic light emitting device 101 includes the color filter layer 103, the color conversion phosphor layer 104 and the transparent flattening layer 105 and the light emitting layer 58 is a blue light emitting layer. Thus, the same members are indicated by the same reference numerals, and description thereof is omitted. The color filter layer 103 is the same as the color filter layer 93. The transparent flattening layer 105 is the same as the transparent flattening layer 95. Thus, description of the color filter layer 103 and the transparent flattening layer 105 is omitted. In a similar manner to the aforementioned embodiments, the light emitting element layer 56 may be constituted by the hole injection layer and the light emitting layer. In addition, the light emitting element layer 56 may be constituted by the light emitting layer and the electron injection layer. Furthermore, the light emitting element layer 56 may be constituted by the hole injection layer, the light emitting layer and a hole transport layer that is located between the hole injection layer and the light emitting layer. Furthermore, the light emitting element layer 56 may be constituted by the light emitting layer, the electron injection layer and an electron transport layer that is located between the light emitting layer and the electron injection layer.

The above-described red light conversion phosphor layer 104R and green light conversion phosphor layer 104G are layers of fluorescent dye, or layers of resins containing fluorescent dye. Examples of fluorescent dye useful for the red light conversion phosphor layer 104R for converting blue light into red fluorescence include cyanine dyes such as 4-dicyanomethylene-2-methyl-6-(p-dimethylamino-styryl)-4H-pyran, pyridine dyes such as 1-ethyl-2-[4-(p-dimethylamino-phenyl)-1,3-butadienyl]-pyridium-perchlorate, rhodamine dyes such as rhodamine B and rhodamine 6G, and oxazine dyes. Examples of fluorescent dye useful for the green light conversion phosphor layer 104G for converting blue light into green fluorescence include coumarin dyes such as 2,3,5,6-1H,4H-tetrahydro-8-trifluoromethyl-quinolizino(9,9a,1-g h)coumarin, 3-(2′-benzothiazolyl)-7-diethylamino-coumarin, and 3-(2′-benzimidazolyl)-7-N,N-diethylaminocoumarin, coumarin-type dyes such as Basic Yellow 51, and naphthalimide dyes such as Solvent Yellow 11 and Solvent Yellow 116. A variety of other dyes including direct dyes, acid dyes, basic dyes, and disperse dyes may be used as well if they are fluorescent. The above-described fluorescent dyes are used singly. Alternatively, two or more of the above-described fluorescent dye may be used in combination. In the case where the red light conversion phosphor layer 104R and the green light conversion phosphor layer 104G are layers of resins containing fluorescent dye, the fluorescent dye contents of the resins may be properly determined with consideration for the fluorescent dye to be used, the thickness of the color conversion phosphor layer, and so forth. For example, the fluorescent dye may be used in an amount of approximately 0.1 to 1 part by weight for 100 parts by weight of the resin.

The blue light dummy layer 104B is for transmitting blue light emitted from the light-emitting device layer 56, as it is, to the color filter layer 103, and it may be a transparent resin layer having a thickness nearly equal to the thickness of the red light conversion phosphor layer 104R or that of the green light conversion phosphor layer 104G.

In the case where the red light conversion phosphor layer 104R and the green light conversion phosphor layer 104G are layers of resins containing fluorescent dye, transparent (transmission for visible light: 50% or more) resins such as polymethyl methacrylate, polyacrylate, polycarbonate, polyvinyl alcohol, polyvinyl pyrrolidone, hydroxyethyl cellulose, carboxymethyl cellulose, polyvinyl chloride resins, melamine resins, phenol resins, alkyd resins, epoxy resins, polyurethane resins, polyester resins, maleic acid resins, and polyamide resins can be used as the resins. Further, in the case where the color conversion phosphor layer 104 is photolithographically patterned, photo-setting resist resins having reactive vinyl groups, such as acrylic resins, methacrylic resins, polyvinyl cinnamate resins, and cyclic rubber resins, are useful. These resins can be used for the above-described blue light dummy layer 104B as well.

When fluorescent dye are used singly to form the red light conversion phosphor layer 104R and the green light conversion phosphor layer 104G, constituent layers of the color conversion phosphor layer 104, such a method as vacuum deposition or sputtering using the desired mask for patterning may be employed to form these layers in a striped pattern. When resins containing fluorescent dye are used to form these layers 104R, 104G, the following method may be employed: a method that a film formed by applying, by such a method as spin coating, roll coating, or cast coating, a coating liquid prepared by dispersing or solubilizing a fluorescent dye and a resin is photolithographically patterned; or a method that a patterned film is formed by screen process printing or the like using the above coating liquid. The following method may be employed to form the blue light dummy layer 104B: a method that a film formed by applying the desired photosensitive resin coating by such a method as spin coating, roll coating, or cast coating is photolithographically patterned; or a method that a patterned film is formed by screen process printing or the like using the desired resin coating liquid.

The thickness of the color conversion phosphor layer 104 is set so that the red light conversion phosphor layer 104R and the green light conversion phosphor layer 104G sufficiently suction blue light emitted by the light emitting element layer 56 and emit fluorescent light. The thickness of the color conversion phosphor layer 104 is set in consideration of a fluorescent dye to be used, the density of the fluorescent dye to be used and the like. For example, the thickness of the color conversion phosphor layer 104 is set to a range of approximately 10 μm to 20 μm. The thickness of the red light conversion phosphor layer 104R may be different from the thickness of the green light conversion phosphor layer 104G.

Examples of organic fluorescent materials that emit blue light include fluorescent whitening agents such as benzothiazole compounds, benzoimidazole compounds, and benzoxazole compounds, metal-chelated oxynoide compounds, styryl benzene compounds, distyryl pyrazine derivatives, and aromatic dimethylidyne compounds.

Specific examples of the fluorescent whitening agents include benzothiazole compounds such as 2-2′-(p-phenylenedivinylene)-bisbenzothiazole; benzoimidazole compounds such as 2-[2-[4-(2-benzoimidazolyl)phenyl]vinyl]benzoimidazole, and 2-[2-(4-carboxy-phenyl)vinyl]benzoimidazole; and benzoxazole compounds such as 2,5-bis(5,7-di-t-pentyl-2-benzoxazolyl)-1,3,4-thiadiazole, 4,4′-bis(5,7-t-pentyl-2-benzoxazolyl)stilbene, and 2-[2-(4-chlorophenyl)vinyl]naphtho[1,2-d]oxazole.

Examples of the metal-chelated oxynoide compounds include 8-hydroxyquinoline metal complexes such as tris(8-quinolinol)aluminum, bis(8-quinolinol)magnesium, and bis(benzo[f]-8-quinolinol)zinc, and dilithium epintridione.

Examples of the styryl benzene compounds include 1,4-bis(2-methylstyryl)benzene, 1,4-bis(3-methylstyryl)benzene, 1,4-bis(4-methylstyryl)benzene, distyryl benzene, 1,4-bis(2-ethylstyryl)benzene, 1,4-bis(3-ethylstyryl)benzene, 1,4-bis(2-methylstyryl)-2-methylbenzene, and 1,4-bis(2-methylstyryl)-2-ethylbenzene.

Examples of the distyryl pyrazine derivatives include 2,5-bis(4-methylstyryl)pyrazine, 2,5-bis(4-ethylstyryl)pyrazine, 2,5-bis[2-(1-naphthyl)vinyl]pyrazine, 2,5-bis(4-methoxystyryl)pyrazine, 2,5-bis[2-(4-biphenyl)vinyl]pyrazine, and 2,5-bis[2-(1-pyrenyl)vinyl]pyrazine.

Examples of the aromatic dimethylidyne compounds include 1,4-phenylenedimethylidyne, 4,4-phenylenedimethylidyne, 2,5-xylene-dimethylidyne, 2,6-naphthylenedimethylidyne, 1,4-biphenylene-dimethylidyne, 1,4-p-terephenylenedimethylidyne, 9,10-anthracene-diyldimethylidyne, 4,4′-bis(2,2-di-t-butylphenylvinyl)biphenyl, and 4,4′-bis(2,2-diphenylvinyl)biphenyl, and derivatives thereof.

Furthermore, compounds represented by the general formula (Rs-Q) 2-AL-O-L (wherein AL is a hydrocarbon having 6 to 24 carbon atoms, containing benzene ring, O-L is a phenylate ligand, Q is a substituted 8-quinolilate ligand, and Rs is an 8-quinolilate substituent selected so that it causes steric hindrance to bonding of two or more substituted 8-quinolinolate ligands) are useful as well for the light-emitting layer. Specific examples of such compounds include bis(2-methyl-8-quinolinolate)(para-phenylphenolate)aluminum (III), and bis(2-methyl-8-quinolinolate)(1-naphtholate)aluminum (III).

The above-described embodiments are only examples, and the present invention is not limited to them. For example, the color filter layer 93, 103 may have black matrices in its film-absent portions.

### EXAMPLES

Next, the present invention is described in detail with examples and is not limited to the examples described below without departing from the gist of the invention.

### First Example

The ink 30 was printed on the substrate 52, while the rotational speed of the printing cylinder 24 included in the printing machine 10 is changed within a range of 10 rpm to 100 rpm.

As the ink 30, the following ink was used: ink that has viscosity of 80 cp (ink temperature: 23° C.) at the shear rate of the ink is 100/second and a boiling point of 186° C. The ink 30 contains a solid of 2.5% by weight and a solvent that has a surface tension of 32 dyne/cm.

As the anilox plate 1, the following anilox plate was used: an anilox plate that includes cells 2 (the density of the cells 2 is 140 lines per inch) and in which the cells 2 have a depth of 40 μm and the proportion of the total area of the cells 2 to the area of a film-formed portion of the anilox plate is 75%.

As the flexographic plate 23 on the printing cylinder 24, a flexographic plate made of a water-developable resin material was used. In this example, the flexographic plate 23 has a resolution of 250 ppi (pixels per inch).

### [Rates to be Evaluated]

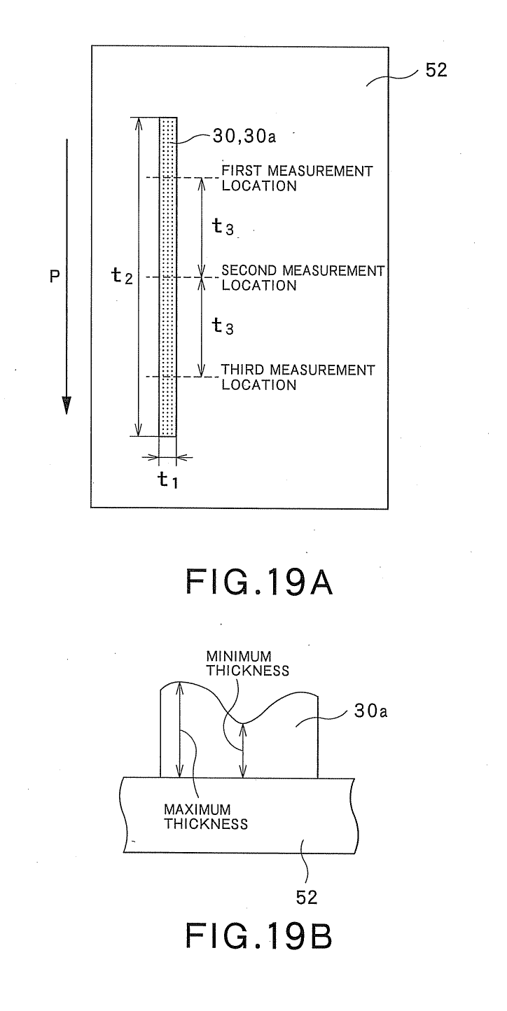

The ink 30 was transferred onto the substrate 52 by the printing machine 10 provided with the aforementioned anilox plate 1 and the aforementioned printing cylinder 24. When the ink 30 was transferred onto the substrate 52, an object 30a (made of the ink 30) was printed on the substrate 52. In this case, as shown in FIG. 19A, the lengths of the projecting portions 23a of the flexographic plate 23 provided on the printing cylinder 24 were set in such a manner that the length t₂ of the printed object 30a in a printing direction P was set to 400 μm. The widths of the projecting portions 23a of the flexographic plate 23, which correspond to the width t₁ of the printed object 30a, were set to 100 μm. The following two rates of the printed object 30a were evaluated.

### (1) Width Variation Rate

First, the widths of portions of the object 30a printed on the substrate 52 were measured. Specifically, as shown in FIG. 19A, the width of a central portion (located at the center of the printed object 30a in a longitudinal direction (printing direction P)) of the printed object 30a, the width of a portion (located on a front side and spaced away from the central portion by a length t₃) of the printed object 30a, and the width of a portion (located on a back side and spaced away from the central portion by the length t₃) of the printed object 30a, were measured. In other words, the width of the portion (located on the back side and spaced away from the central portion by the length t₃) of the printed object 30a was measured at a first measurement location; the width of the central portion of the printed object 30a was measured at a second measurement location; and the width of the portion (located on the front side and spaced away from the central portion by the length t₃) of the printed object 30a was measured at a third measurement location. In this case, the length t₃ was set to 130 μm. Next, the average width of the measured widths, the maximum width among the measured widths, and the minimum width among the measured widths were calculated. After that, a width variation rate (%) was calculated using the following equation on the basis of the average width, the maximum width and the minimum width.

Width variation rate (%)={(maximum width−minimum width)/average width}×100

### (2) Thickness Variation Rate

First, the thicknesses of the multiple portions of the object 30a printed on the substrate 52 were measured. Next, the average thickness of the measured thicknesses, the maximum thickness among the measured thicknesses and the minimum thickness among the measured thicknesses were calculated. After that, a thickness variation rate (%) was calculated using the following equation on the basis of the average thickness, the maximum thickness and the minimum thickness.

Thickness variation rate (%)={(maximum thickness−minimum thickness)/average thickness}×100

While the rotational speed of the printing cylinder 24 that rotates above the surface plate 6 was changed within the range of 10 rpm to 100 rpm, the width variation rates of the printed object 30a were evaluated. The evaluation results are shown in Table 1. In Table 1, when the width variation rate is 5% or less, it is determined that the printed object 30a is passed. When the width variation rate is larger than 5%, it is determined that the printed object 30a fails.

TABLE 1

| | | Rotational speed of printing | | | | | | |
|---|---|---|---|---|---|---|---|---|
| | | cylinder (rpm) | | | | | | |
| | | 10 | 15 | 20 | 35 | 40 | 60 | 100 |
| Width of | First | 180.3 | 156.47 | 159.34 | 158.448 | 165.285 | 168.236 | 169.34 |
| printed | measurement | | | | | | | |
| object | location | | | | | | | |
| (μm) | Second | 167.3 | 163.942 | 158.128 | 155.983 | 162.535 | 167.215 | 168.214 |
| | measurement | | | | | | | |
| | location | | | | | | | |
| | Third | 150.8 | 166.157 | 166.079 | 162.823 | 168.285 | 170.834 | 171.24 |
| | measurement | | | | | | | |
| | location | | | | | | | |

| | | | | | | | |
|---|---|---|---|---|---|---|---|
| Range (=max-min) | 29.5 | 9.687 | 7.951 | 6.84 | 5.75 | 3.619 | 3.026 |
| Width variation rate (%) | 17.8 | 6.0 | 4.9 | 4.3 | 3.5 | 2.1 | 1.8 |
| Result | Fail | Fail | Passed | Passed | Passed | Passed | Passed |

As shown in Table 1, when the printing cylinder 24 was controlled by the control means 9 so that the rotational speed of the printing cylinder 24 was set to 20 rpm or higher, the width variation rate of the object 30a printed on the substrate 52 was 5% or less. Especially, when the printing cylinder 24 was controlled by the control means 9 so that the rotational speed of the printing cylinder 24 was set to 40 rpm or higher, the width variation rate of the object 30a printed on the substrate 52 was 4% or less. The results are more preferable. In contrast, it was confirmed that when the rotational speed of the printing cylinder 24 was less than 20 rpm, the width of the printed object 30a was smaller toward the front side in the printing direction P. Thus, when the rotational speed of the printing cylinder 24 was less than 20 rpm, the width variation rate of the printed object 30a was larger than 5%.

While the rotational speed of the printing cylinder 24 provided in the printing machine 10 was changed within the range of 10 rpm to 100 rpm, the thickness variation rates of the printed object 30a were evaluated. The evaluation results are shown in Table 2. In Table 2, when the thickness variation rate is 5% or less, it is determined that the printed object 30a is passed. When the thickness variation rate is larger than 5%, it is determined that the printed object 30a fails.

TABLE 2

| | Rotational speed of printing | | | | | | |
|---|---|---|---|---|---|---|---|
| | cylinder (rpm) | | | | | | |
| | 10 | 15 | 20 | 35 | 40 | 60 | 100 |
| Thickness | 11.50 | 6.90 | 4.80 | 4.50 | 3.90 | 3.7 | 3.50 |
| variation | | | | | | | |
| rate (%) | | | | | | | |
| Determi- | Fail | Fail | Passed | Passed | Passed | Passed | Passed |
| nation | | | | | | | |

As shown in Table 2, when the printing cylinder 24 was controlled by the control means 9 so that the rotational speed of the printing cylinder 24 was set to 20 rpm or higher, the thickness variation rate of the object 30a printed on the substrate 52 was 5% or less. Especially, when the printing cylinder 24 was controlled by the control means 9 so that the rotational speed of the printing cylinder 24 was set to 40 rpm or higher, the thickness variation rate of the object 30a printed on the substrate 52 was 4% or less. The results are more preferable. In contrast, it was confirmed that when the rotational speed of the printing cylinder 24 was less than 40 rpm, the thickness variation rate of the printed object 30a was larger than 5%.

### Second Example

While the resolution of the flexographic plate 23 on the printing cylinder 24 was changed within a range of 40 ppi to 250 ppi, the ink 30 was printed on the substrate 52. In this case, the rotational speed of the printing cylinder 24 that rotates on the anilox plate 1 was set to 20 rpm, while the rotational speed of the printing cylinder 24 that rotates above the surface plate 6 was set to 100 rpm. Other conditions were the same as the conditions in the first example, and description thereof is omitted.

The thicknesses of multiple portions of an object 30a made of the ink 30 and printed on the substrate 52 were measured, and the thickness variation rates of the printed object 30a were calculated. The calculated thickness variation rates are shown in Table 3. In Table 3, when the thickness variation rate is 5% or less, it is determined that the printed object 30a is passed. When the thickness variation rate is larger than 5%, it is determined that the printed object 30a fails.

TABLE 3

| | Thickness variation | |
|---|---|---|
| Resolution (ppi) | rate (%) | Determination |
| 40 | 16 | Fail |
| 80 | 10.8 | Fail |
| 95 | 5.3 | Fail |
| 100 | 4.5 | Passed |
| 120 | 3.7 | Passed |
| 200 | 3.7 | Passed |
| 250 | 3.6 | Passed |

As shown in Table 3, when the resolution of the flexographic plate 23 was 100 ppi or higher, the thickness variation rate of the object 30a printed on the substrate 52 was 5% or less. Especially, when the resolution of the flexographic plate 23 was 120 ppi or higher, the thickness variation rate of the object 30a printed on the substrate 52 was 4% or less. The results are more preferable. In contrast, when the resolution of the flexographic plate 23 was lower than 100 ppi, the thickness variation rate of the object 30a printed on the substrate 52 was larger than 5%. It can be said that as the resolution of the flexographic plate 23 is lower or the area of the object 30a printed on the substrate 52 is larger, the difference between the maximum value among the thicknesses of the portions of the printed object 30a and the minimum value among the thicknesses of the portions of the printed object 30a is larger.

### Third Example

While various types of ink were used, the ink was printed on the substrate 52 by the printing machine 10. In the third example, the viscosity of the ink was focused among various characteristics of the ink. The rotational speed of the printing cylinder 24 that rotates on the anilox plate 1 was set to 20 rpm, while the rotational speed of the printing cylinder 24 that rotates above the surface plate 6 was set to 100 rpm. Other conditions were the same as the conditions in the first example, and description thereof is omitted.

First, various types of ink that has viscosity of 8.97 cP to 320 cP (ink temperature: 23° C.) at the shear rate of the ink is 100/second were prepared. Next, these types of ink were printed on the substrate 52 by the printing machine 10. After that, the thicknesses of multiple portions of an object 30a made of the ink and printed on the substrate 52 were measured, and the thickness variation rates of the printed object 30a were calculated. Characteristics of each of the types of ink and the calculated thickness variation rates are shown in Table 4. In Table 4, when the thickness variation rate is 5% or less, it is determined that the printed object 30a is passed. When the thickness variation rate is larger than 5%, it is determined that the printed object 30a fails.

TABLE 4

| Characteristics of ink | | | | | |
|---|---|---|---|---|---|
| | Solid | Surface | Boiling | Thickness | |
| Viscosity | (weight | tension | point | variation | |
| (cP) | %) | (dyne/cm) | (° C.) | rate (%) | Determination |
| 8.97 | 1.5 | 28.3 | 164 | 20.5 | Fail |
| 21.2 | 2 | 28.3 | 164 | 18.6 | Fail |
| 24.8 | 1.5 | 31.8 | 185 | 12.2 | Fail |
| 32 | 2 | 28.3 | 164 | 11.3 | Fail |
| 37.9 | 1.5 | 35.5 | 207 | 12.4 | Fail |
| 41.7 | 2.5 | 28.3 | 164 | 16.8 | Fail |
| 46.6 | 1.5 | 34.8 | 240 | 7.5 | Fail |
| 52 | 2 | 31.8 | 185 | 2.3 | Passed |
| 60 | 2.5 | 30.8 | 181 | 3.1 | Passed |
| 78 | 2.5 | 31.8 | 185 | 1.9 | Passed |
| 94.3 | 2 | 35.5 | 207 | 3.9 | Passed |
| 120 | 2 | 34.8 | 240 | 3.2 | Passed |
| 125 | 2.8 | 31.8 | 185 | 3.3 | Passed |
| 192 | 3 | 31.8 | 185 | 4.5 | Passed |
| 245 | 2.8 | 35.5 | 207 | 8.4 | Fail |
| 320 | 2.8 | 34.8 | 240 | 11.8 | Fail |

As shown in Table 4, when the viscosity of the ink was in a range of 52 cP to 192 cP, the thickness variation rate of the object 30a printed on the substrate 52 was 5% or less. In contrast, when the viscosity of the ink was 46.6 or less, the thickness variation rate of the object 30a printed on the substrate 52 was larger than 5%. It is considered that an irregularity in the thickness of the ink printed on the substrate occurred due to the fact that the viscosity of the ink is small or the boiling point of the ink is high. In addition, when the viscosity of the ink was 245 cP or higher, the thickness variation rate of the object 30a printed on the substrate 52 was larger than 5%. This may be attributable to a leveling failure caused by the large viscosity of the ink.

### Fourth Example

While various types of ink were used, the ink was printed on the substrate 52 by the printing machine 10. In the fourth example, the surface tension of a solvent contained in the ink was focused among various characteristics of the ink. The rotational speed of the printing cylinder 24 that rotates on the anilox plate 1 was set to 20 rpm, while the rotational speed of the printing cylinder 24 that rotates above the surface plate 6 was set to 100 rpm. Other conditions were the same as the conditions in the first example, and description thereof is omitted.

First, various types of ink that contain a solvent having a surface tension of 30.8 dyne/cm to 39 dyne/cm were prepared. Next, these types of ink were printed on the substrate 52 by the printing machine 10. After that, the thicknesses of multiple portions of an object 30a made of the ink and printed on the substrate 52 were measured, and the thickness variation rates of the printed object 30a were calculated. Characteristics of each of the types of ink and the calculated thickness variation rates are shown in Table 5. In Table 5, when the thickness variation rate is 5% or less, it is determined that the printed object 30a is passed. When the thickness variation rate is larger than 5%, it is determined that the printed object 30a fails.

TABLE 5

| Characteristics of ink | | | | | |
|---|---|---|---|---|---|
| Surface | Solid | | Boiling | Thickness | |
| tension | (weight | Viscosity | point | variation | |
| (dyne/cm) | %) | (cP) | (° C.) | rate (%) | Determination |
| 30.8 | 2.5 | 60 | 181 | 3.1 | Passed |
| 31.8 | 2.5 | 78 | 185 | 2.3 | Passed |
| 34.8 | 2 | 120 | 240 | 3.2 | Passed |
| 35.5 | 2 | 94.3 | 207 | 3.9 | Passed |
| 36.8 | 2 | 183 | 245 | 4.5 | Passed |
| 39 | 1.5 | 123 | 268 | 5.9 | Fail |

As shown in Table 5, when the surface tension of the solvent contained in the ink was in a range of 30.8 dyne/cm to 36.8 dyne/cm, the thickness variation rate of the object 30a printed on the substrate 52 was 5% or less. Especially, when the surface tension of the solvent contained in the ink was 30.8 dyne/cm to 35.5 dyne/cm, the thickness variation rate of the object 30a printed on the substrate 52 was 4% or less. The results are more preferable.

In contrast, when the surface tension of the solvent contained in the ink was 39 dyne/cm, the thickness variation rate of the object 30a printed on the substrate 52 was larger than 5%. This may be attributable to a leveling failure caused by the fact that the surface tension of the solvent contained in the ink is large and the boiling point of the ink is high.

### Fifth Example

While various types of ink were used, the ink was printed on the substrate 52 by the printing machine 10. In the fifth example, the boiling point of a solvent contained in the ink was focused among various characteristics of the ink. The rotational speed of the printing cylinder 24 that rotates on the anilox plate 1 was set to 20 rpm, while the rotational speed of the printing cylinder 24 that rotates above the surface plate 6 was set to 100 rpm. Other conditions were the same as the conditions in the first example, and description thereof is omitted.

First, various types of ink that contain a solvent having a boiling point of 164° C. to 268° C. were prepared. Next, these types of ink were printed on the substrate 52 by the printing machine 10. After that, the thicknesses of multiple portions of an object 30a made of the ink and printed on the substrate 52 were measured, and the thickness variation rates of the printed object 30a were calculated. Characteristics of each of the types of ink and the calculated thickness variation rates are shown in Table 6. In Table 6, when the thickness variation rate is 5% or less, it is determined that the printed object 30a is passed. When the thickness variation rate is larger than 5%, it is determined that the printed object 30a fails.

TABLE 6

| Characteristics of ink | | | | | |
|---|---|---|---|---|---|
| Boiling | | Solid | Surface | Thickness | |
| point | Viscosity | (weight | tension | variation | |
| (° C.) | (cP) | %) | (dyne/cm) | rate (%) | Determination |
| 164 | 41.7 | 2.5 | 28.3 | 16.8 | Fail |
| 185 | 78 | 2.5 | 31.8 | 1.9 | Passed |
| 207 | 94.3 | 2 | 35.5 | 3.9 | Passed |
| 240 | 120 | 2 | 34.8 | 3.2 | Passed |
| 245 | 183 | 2 | 36.8 | 4.5 | Passed |
| 268 | 123 | 1.5 | 39 | 5.9 | Fail |

As shown in Table 6, when the boiling point of the solvent contained in the ink was in a range of 185° C. to 245° C., the thickness variation rate of the object 30a printed on the substrate 52 was 5% or less. Especially, when the boiling point of the solvent contained in the ink was in a range of 185° C. to 240° C., the thickness variation rate of the object 30a printed on the substrate 52 was 4% or less. The results are more preferable.

In contrast, when the boiling point of the solvent contained in the ink was 164° C., the thickness variation rate of the object 30a printed on the substrate 52 was larger than 5%. It is considered that an irregularity in the thickness of the ink printed on the substrate 52 occurred due to the fact that the boiling point of the solvent contained in the ink is low and the viscosity of the ink is small. When the boiling point of the solvent contained in the ink was 268° C., the thickness variation rate of the object 30a printed on the substrate 52 was larger than 5%. This may be attributable to a leveling failure caused by the high boiling point and the low surface tension of the solvent contained in the ink.

### Sixth Example

While various types of ink were used, the ink was printed on the substrate 52 by the printing machine 10. In the sixth example, the weight percent of a solid contained in the ink was focused among various characteristics of the ink. As the ink, the ink for the red light emitting layers was used. In the sixth example, the surface tension of a solvent contained in the ink of each of the types was 31.8 dyne/cm, and the boiling point of the solvent contained in the ink of each of the types was 185° C. The rotational speed of the printing cylinder 24 that rotates on the anilox plate 1 was set to 20 rpm, while the rotational speed of the printing cylinder 24 that rotates above the surface plate 6 was set to 100 rpm. Other conditions were the same as the conditions in the first example, and description thereof is omitted.

First, various types of ink that contain a solid with a content of 1 to 4.5% by weight were prepared. Next, these types of ink were printed on the substrate 52 by the printing machine 10. After that, the thicknesses of multiple portions of an object 30a made of the ink and printed on the substrate 52 were measured. Characteristics of each of the types of ink and the measured thickness are shown in Table 7. In Table 7, when the thickness of the printed object 30a is in a range of 70 nm to 120 nm, it is determined that the printed object 30a is passed. When the thickness of the printed object 30a is not in the range of 70 nm to 120 nm, it is determined that the printed object 30a fails.

TABLE 7

Characteristics of ink

| Solid | Viscosity | Thickness | |
|---|---|---|---|
| (weight %) | (cP) | (nm) | Determination |
| 1 | 41 | <70 | Fail |
| 1.5 | 52 | 72 | Passed |
| 2 | 55 | 83 | Passed |
| 2.5 | 60 | 90 | Passed |
| 3 | 130 | 100 | Passed |
| 4 | 180 | 115 | Passed |
| 4.5 | 220 | 123 | Fail |
| 5 | 280 | 135 | Fail |

As shown in Table 7, when the weight percent of the solid contained in the ink was in a range of 1.5 to 4, the thickness of the object 30a printed on the substrate 52 was in a range of 70 nm to 120 nm. In contrast, when the weight percent of the solid contained in the ink was 4.5 or 5, the thickness of the object 30a printed on the substrate 52 was larger than 120 nm. This may be due to the fact that a dissolved solid remains or the viscosity of the ink was excessively increased depending on the used solvent. In addition, when the weight percent of the solid contained in the ink was 1, the thickness of the object 30a printed on the substrate 52 was smaller than 70 nm. It can be said that the weight percent of the solid contained in the ink is preferably in a range of 1.5 to 4 on the basis of the aforementioned results.

### Seventh Example

While the anilox plate 11 that includes the cells 12 arranged in a matrix pattern was used in the printing machine 10, the ink 30 was printed on the substrate 52. In this case, the boiling point of the solvent contained in the ink 30 was 185° C.; the surface tension of the solvent contained in the ink 30 was 31.8 dyne/cm; the content of the solid in the ink 30 was 2.5% by weight; and the viscosity of the ink 30 was 78 cP. The rotational speed of the printing cylinder 24 that rotates on the anilox plate 1 was set to 20 rpm, while the rotational speed of the printing cylinder 24 that rotates above the surface plate 6 was set to 100 rpm. Other conditions were the same as the conditions in the first example, and description thereof is omitted.

(Evaluation while the Density of Cells is Changed)

First, while the density of the cells 12 on the anilox plate 11 was changed within a range of 95 to 340 lines per inch, the ink 30 was printed on the substrate 52. The thicknesses of multiple portions of an object 30a made of the ink 30 and printed on the substrate 52 were measured. In addition, the thickness variation rates of the printed object 30a were calculated on the basis of the results of the measurement of the multiple portions of the printed object 30a. The average (average thickness) of the measured thicknesses and the calculated thickness variation rates are shown in Table 8. In Table 8, when the average thickness is in a range of 70 nm to 120 nm and the thickness variation rate is 5% or less, it is determined that the printed object 30a is passed. When the average thickness is not in the range of 70 nm to 120 nm or the thickness variation rate is larger than 5%, it is determined that the printed object 30a fails. In Table 8, an area proportion indicates the proportion of the total area of the cells 12 to the area of the film-formed portion (constituted by the cells 12 and the non-cell portion 13) of the anilox plate 11.

TABLE 8

| Anilox plate | | | | | |
|---|---|---|---|---|---|
| Density | Area | Depths | Average | Thickness | |
| (lines/ | proportion | of cells | thickness | variation | |
| inch) | (%) | (μm) | (nm) | rate (%) | Determination |
| 95 | 85 | 40 | 119 | 8 | Fail |
| 100 | 85 | 40 | 100 | 4.8 | Passed |
| 120 | 85 | 40 | 92 | 3.2 | Passed |
| 150 | 85 | 40 | 85 | 2.5 | Passed |
| 200 | 85 | 40 | 83 | 2.4 | Passed |
| 250 | 85 | 40 | 75 | 2.1 | Passed |
| 300 | 85 | 40 | 72 | 1.9 | Passed |
| 320 | 85 | 40 | 68 | 2.3 | Fail |
| 340 | 85 | 40 | 60 | 2.4 | Fail |

As shown in Table 8, when the density of the cells 12 on the anilox plate 11 was in a range of 100 lines per inch to 300 lines per inch, the average thickness of the object 30a printed on the substrate 52 was in a range of 70 nm to 120 nm, and the thickness variation rate was 5% or less. Especially, when the density of the cells 12 on the anilox plate 11 was in a range of 120 lines per inch to 200 lines per inch, the average thickness of the object 30a printed on the substrate 52 was 80 nm or larger, and the thickness variation rate was 4% or less. The results are more preferable.

In contrast, when the density of the cells 12 on the anilox plate 11 was 95 lines per inch, the thickness variation rate of the object 30a printed on the substrate 52 was larger than 5%. It is considered that an irregularity of the ink 30 printed on the substrate 52 was large since the area of each of the cells 12 was large. In addition, when the density of the cells 12 on the anilox plate 11 was larger than 300 lines per inch, the thickness of the object 30a printed on the substrate 52 was smaller than 70 nm.

(Evaluation while Area Proportion of Cells is Changed)

Next, while the area proportion (proportion of the total area of the cells 12 to the area of the film-formed portion of the anilox plate 11) of the cells 12 on the anilox plate 11 was changed within a range of 50% to 95%, the ink 30 was printed on the substrate 52. The thicknesses of multiple portions of an object 30a printed on the substrate 52 were measured. In addition, the thickness variation rates of the printed object 30a were calculated on the basis of the results of the measurement of the thicknesses of the multiple portions of the printed object 30a. The average (average thickness) of the measured thicknesses of the portions of each of the printed objects 30a and the calculated thickness variation rates are shown in Table 9. In Table 9, when the average thickness is in a range of 70 nm to 120 nm and the thickness variation rate is 5% or less, it is determined that the printed object 30a is passed. When the average thickness is not in a range of 70 nm to 120 nm or the thickness variation rate is larger than 5%, it is determined that the printed object 30a fails.

TABLE 9

| Anilox plate | | | | | |
|---|---|---|---|---|---|
| Density | Area | Depths of | Average | Thickness | |
| (lines/ | proportion | cells | thickness | variation | |
| inch) | (%) | (μm) | (nm) | rate (%) | Determination |
| 150 | 95 | 40 | 92 | 3 | Passed |
| 150 | 85 | 40 | 85 | 1.9 | Passed |
| 150 | 70 | 40 | 84 | 3 | Passed |
| 150 | 60 | 40 | 80 | 4 | Passed |
| 150 | 55 | 40 | 75 | 4 | Passed |
| 150 | 50 | 40 | 68 | 5 | Fail |

As shown in Table 9, when the area proportion of the cells 12 on the anilox plate 11 was in a range of 55% to 95%, the average thickness of the object 30a printed on the substrate 52 was in a range of 70 nm to 120 nm, and the thickness variation rate was 5% or less. Especially, when the area proportion of the cells 12 on the anilox plate 11 was in a range of 70% to 95%, the average thickness of the object 30a printed on the substrate 52 was larger than 80 nm. The results are more preferable.

In contrast, when the area proportion of the cells 12 on the anilox plate 11 was 50%, the average thickness of the object 30a printed on the substrate 52 was smaller than 70 nm.

(Evaluation while the Depths of Cells are Changed)

Next, while the depths of the cells 12 on the anilox plate 11 are changed within a range of 12 μm to 110 μm, the ink 30 was printed on the substrate 52. The thicknesses of multiple portions of an object 30a made of the ink 30 and printed on the substrate 52 were measured. In addition, the thickness variation rates of the printed object 30a were calculated on the basis of the results of the measurement of the thicknesses of the multiple portions of the printed object 30a. The average (average thickness) of the measured thicknesses of the multiple portions of the printed object 30a and the thickness variation rates are shown in Table 10. In Table 10, when the average thickness is in a range of 70 nm to 120 nm and the thickness variation rate is 5% or less, it is determined that the printed object 30a is passed. When the average thickness is not in the range of 70 nm to 120 nm or the thickness variation rate is larger than 5%, it is determined that the printed object 30a fails.

TABLE 10

| Anilox plate | | | | | |
|---|---|---|---|---|---|
| Density | Area | Depths of | Average | Thickness | |
| (lines/ | proportion | cells | thickness | variation | |
| inch) | (%) | (μm) | (nm) | rate (%) | Determination |
| 150 | 85 | 12 | 45 | 1.7 | Fail |
| 150 | 85 | 14 | 62 | 1.7 | Fail |
| 150 | 85 | 16 | 73 | 1.8 | Passed |
| 150 | 85 | 20 | 80 | 1.8 | Passed |
| 150 | 85 | 40 | 85 | 1.9 | Passed |
| 150 | 85 | 80 | 87 | 3.8 | Passed |
| 150 | 85 | 100 | 87 | 4.2 | Passed |
| 150 | 85 | 110 | 90 | 9 | Fail |

As shown in Table 10, when the depths of the cells 12 on the anilox plate 11 were in a range of 16 μm to 100 μm, the average thickness of the object 30a printed on the substrate 52 was in a range of 70 nm to 120 nm and the thickness variation rate was 5% or less. Especially, when the depths of the cells 12 on the anilox plate 11 were in a range of 16 μm to 80 μm, the thickness variation rate of the object 30a printed on the substrate 52 was 4% or less. The results are more preferable.

In contrast, when the depths of the cells 12 on the anilox plate 11 were in a range of 12 μm to 14 μm, the average thickness of the object 30a printed on the substrate 52 was smaller than 70 nm. In addition, when the depths of the cells 12 on the anilox plate 11 were 110 μm, the thickness variation rate of the object 30a printed on the substrate 52 was larger than 5%.

### Eighth Example

While the anilox plate 1 that includes the cells 2 arranged in a striped pattern was used in the printing machine 10, the ink 30 was printed on the substrate 52. Specifically, while the ratio b/a of the width b of each of the cells 2 (provided on the anilox plate 1) in the printing direction P to the width a of the cell in a direction perpendicular to the printing direction P was changed within a range of 0.5 to 1000, the ink 30 was printed on the substrate 52. In this example, the direction in which the cells 2 extend is parallel to the printing direction P (refer to FIG. 3A). In addition, the density of the cells 2 was set to 150 lines per inch, the area proportion of the cells 2 was set to 85%, and the depths of the cells were set to 40 μm. Other conditions were the same as the conditions in the seventh example, and description thereof is omitted.

While the ratio b/a of each of the cells 2 was changed within the range of 0.5 to 1000, the ink 30 was printed on the substrate 52. The thicknesses of multiple portions of an object 30a made of the ink 30 and printed on the substrate 52 were measured. In addition, the thickness variation rates of the printed object 30a were calculated on the basis of the results of the measurement of the thicknesses of the multiple portions of the printed object 30a. The calculated thickness variation rates are shown in Table 11. In Table 11, when the thickness variation rate is 5% or less, it is determined that the printed object 30a is passed. When the thickness variation rate is larger than 5%, it is determined that the printed object 30a fails.

TABLE 11

| Anilox plate | Thickness variation | |
|---|---|---|
| Ratio b/a | rate (%) | Determination |
| 0.5 | 8.2 | Fail |
| 0.55 | 5.8 | Fail |
| 0.65 | 4.7 | Passed |
| 0.8 | 4 | Passed |
| 1 | 3 | Passed |
| 2 | 3 | Passed |
| 1000 | 4.6 | Passed |

As shown in Table 11, when the ratio b/a of each of the cells 2 on the anilox plate 1 was in a range of 0.65 to 1000, the thickness variation rate of the object 30a printed on the substrate 52 was 5% or less. Especially, when the ratio b/a of each of the cells 2 on the anilox plate 1 was in a range of 1 to 1000, the thickness variation rate of the object 30a printed on the substrate 52 was 3% or less. The results are more preferable.

In contrast, when the ratio b/a of each of the cells 2 on the anilox plate 1 was 0.55 or less, the thickness variation rate of the object 30a printed on the substrate 52 was larger than 5%.

### Ninth Example

The light emitting efficiency of the organic light emitting device according to the present invention was evaluated when the luminance of light emitted by the organic light emitting device is 1000 cd/m². In addition, the time for reducing the luminance by half was evaluated as a device lifetime while the organic light emitting device was driven with a constant current. First, a process of forming the organic light emitting device according to the present invention is described below.

### (Formation of Transparent Electrode Layers)

First, an indium tin oxide (ITO) electrode film having a thickness of 200 nm was formed on the transparent substrate 52 (having a thickness of 0.7 mm) by an ion plating method. Then, a photosensitive resist was coated on the ITO electrode film, exposed to light through a mask and then developed, and the ITO electrode film was etched so that 10 stripe-like portions of a transparent electrode layer 53, which have a width of 2.2 mm, were formed and arranged at pitches of 4 mm.

### (Formation of Insulating Layer)

Next, the transparent substrate 52 (having a thickness of 0.7 mm) was subjected to a cleaning process and an ultraviolet plasma cleaning process. After that, negative type photosensitive resin was coated on the substrate by a spin coating method and patterned by a photolithographic process. Then, the insulating layer 54 (having a thickness of 1 μm) was formed so that the light emitting areas (openings 55) having an area of 2 mm×2 mm are located on the stripe-like portions of the transparent electrode layer 53, respectively, and arranged at pitches of 4 mm.

### (Formation of Hole Injection Layer)

The hole injection layer 57 was formed solidly in the openings 55 and on the insulating layer 54 by a gravure offset printing method. The thickness of the hole injection layer 57 was set to 75 nm.

### (Formation of Light Emitting Layer)

The light emitting layer 58 (red light emitting layer 58R) was formed above the hole injection layer 57 by the printing method according to the present invention.

As the ink 30 that is printed by the printing machine 10 in the printing method, the following ink was used: ink that has viscosity of 80 cP (when the shear rate of the ink is 100/second and the temperature of the ink is 23° C.) and a boiling point of 186° C. In addition, the weight percent of the solid contained in the ink 30 was set to 2.5, and the surface tension of the solvent contained in the ink 30 was set to 32 dyne/cm.

As the anilox plate 1 included in the printing machine 10, the following anilox plate was used: an anilox plate that has cells 2 that have a depth of 40 μm and are arranged in a matrix pattern while the density of the cells 2 is 140 lines per inch. In the anilox plate, the proportion of the total area of the cells to the area of a film-formed portion of the anilox plate is 75%.

As the flexographic plate 23 on the printing cylinder 24 provided in the printing machine 10, the following flexographic plate was used: a flexographic plate that is mage of a resin material that can be engraved using a laser. The resolution of the flexographic plate 23 was set to 250 ppi. The printing cylinder 24 was controlled by the control means 9 in such a manner that the printing cylinder 24 rotated above the surface plate 6 at a rotational speed of 100 rpm.

The light emitting layer 58 (the red light emitting layer 58 R) having a thickness of 90 nm was formed above the hole injection layer 57 by the thus configured printing machine 10.

### (Formation of Electron Injection Layer)

A metal mask that has stripe-like openings was placed on the side of the surface of the light emitting layer 58 so that the openings of the metal mask are located on the light emitting areas (openings 55) of the insulating layer 54 and extend in a direction perpendicular to a direction in which the stripe-like transparent electrode layers 53 extend. The openings of the metal mask have a width of 2.2 mm and are arranged at pitches of 4 mm. Next, calcium was deposited through the metal mask by a vacuum deposition method (the deposition rate was set to 0.1 nm/second) so that 10 portions of the electron injection layer 59 (having a thickness of 10 nm) were formed and arranged at pitches of 4 mm.

### (Formation of Electrode Layer)

Next, aluminum was deposited by a vacuum deposition method (the deposition rate was set to 0.4 nm/second) using the metal mask that was used for the formation of the electron injection layer 59. In this manner, the stripe-like electrode layer 60 (having a thickness of 300 nm and a width of 2.2 mm) made of aluminum was formed on the electron injection layer 59.

Lastly, a sealing plate is attached on the side of the surface of the electrode layer through an ultraviolet-curing adhesive. In this manner, the organic light emitting device according to the present invention was formed.

The light emitting efficiency of the organic light emitting device according to the present invention was evaluated while the luminance of light emitted by the organic light emitting device was 1000 cd/m². In addition, the time for reducing the luminance by half was evaluated as a device lifetime while the organic light emitting device was driven with a constant current. The light emitting efficiency was 0.83 cd/A, and the device lifetime was 11000 hours. The device lifetime was evaluated in the following manner. The value of a current was set so that the initial luminance was 100 cd/m². While the organic light emitting device was continuously driven with the aforementioned current, and the time for reducing the initial luminance by half to 50 cd/m² was measured.

### Comparative Example

An organic light emitting device was formed while a spin coating method was used as a printing method for forming a light emitting layer, and other conditions were the same as the conditions in the ninth example. In the organic light emitting device, a hole injection layer had the average thickness of 40 nm, and a red light emitting layer had the average thickness of 60 nm.

The light emitting efficiency of the organic light emitting device was evaluated while the luminance of light emitted by the organic light emitting device was set to 1000 cd/m². In addition, the time for reducing the luminance by half was evaluated as a device lifetime while the organic light emitting device was driven with a constant current. The light emitting efficiency was 0.8 cd/A, and the device lifetime was 6000 hours. Thus, the light emitting efficiency and the device lifetime in the comparative example were worse than the light emitting efficiency and the device lifetime in the ninth example.

What is claimed is:

1. A method for performing flexographic printing using a sheet-fed printing machine, comprising the steps of:
placing a substrate on a surface plate that is fixed to and located on a frame;
supplying ink onto a flat anilox plate that is fixed to and located on the frame, the anilox plate having a plurality of cells formed on an upper surface of the anilox plate;
moving a printing cylinder in a rotating manner on the anilox plate so that a flexographic plate provided on the printing cylinder receives the ink from the cells of the anilox plate; and
moving the printing cylinder on the substrate located on the surface plate so that the received ink is transferred from the flexographic plate on the printing cylinder onto the substrate;
wherein the viscosity of the ink is in a range of 51 cP to 200 cP (ink temperature: 23° C.) at the shear rate of 100/second,
the flexographic plate on the printing cylinder is made of an elastic material, and
the printing cylinder rotates on the substrate at a rotational speed of 20 rpm or higher when the printing cylinder moves in a rotating manner on the substrate.

2. The printing method according to claim 1,
wherein the ink contains a solvent and a solid that is dissolved in the solvent, and
the surface tension of the solvent is 37 dyne/cm or less, and the boiling point of the solvent is in a range of 165° C. to 265° C.

3. The printing method according to claim 2,
wherein the content of the solid in the ink is in a range of 1.5 to 4.0% by weight.

4. The printing method according to claim 1,
wherein the anilox plate has a plurality of cells arranged on the upper surface of the anilox plate in a matrix pattern, the plurality of cells being filled with the ink,
the density of the cells is in a range of 100 lines per inch to 300 lines per inch in the anilox plate, and the proportion of the total area of the cells to the area of a film-formed portion of the anilox plate is in a range of 55% to 95%, and
the depths of the cells are in a range of 15 μm to 100 μm.

5. The printing method according to claim 1,
wherein the anilox plate has a plurality of cells arranged on the upper surface of the anilox plate in a striped pattern, the plurality of cells being filled with the ink,
the density of the cells is in a range of 100 lines per inch to 300 lines per inch in the anilox plate, and the proportion of the total area of the cells to the area of a film-formed portion of the anilox plate is in a range of 55% to 95%,
the depths of the cells are in a range of 15 μm to 100 μm, and
for each of the cells, the ratio of the maximum width of the cell in a printing direction to the maximum width of the cell in a direction perpendicular to the printing direction is 0.6 or larger.

6. The printing method according to claim 1,
wherein the flexographic plate provided on the printing cylinder is made of a water-developable resin material.

7. The printing method according to claim 1,
wherein the flexographic plate provided on the printing cylinder is made of a resin material that can be engraved with a laser.

8. The printing method according to claim 1,
wherein the printing cylinder includes a metal roll and a flexographic plate that is fixed to an outer circumferential surface of the metal roll with an adhesive.

9. The printing method according to claim 1,
wherein the printing cylinder includes a metal roll, a cylindrical plastic sleeve surrounding the metal roll, and a flexographic plate arranged on an outer circumferential surface of the plastic sleeve, and
the plastic sleeve is arranged on the metal roll and fixed to the metal roll by an air clamping mechanism that is arranged in the metal roll.

10. The printing method according to claim 1,
wherein the printing cylinder includes a metal roll, a cylindrical plastic sleeve surrounding the metal roll, and a flexographic plate arranged on an outer circumferential surface of the plastic sleeve, and
the plastic sleeve is arranged on the metal roll and fixed to the metal roll by an suction mechanism that is arranged in the metal roll.

11. A method for forming a light emitting layer in an organic light emitting device using a flexographic printing method, the organic light emitting device including electrodes facing each other and a light emitting element layer, the light emitting element layer being arranged between the electrodes and having at least the light emitting layer, comprising the steps of:
placing a substrate on a surface plate that is fixed to and located on a frame;
supplying ink containing at least an organic light emitting material onto a flat anilox plate that is fixed to and located on the frame, the anilox plate having a plurality of cells formed on an upper surface of the anilox plate;
moving a printing cylinder in a rotating manner on the anilox plate so that a flexographic plate provided on the printing cylinder receives the ink from the cells on the anilox plate; and
moving the printing cylinder on the substrate located on the surface plate so that the received ink is transferred from the flexographic plate onto the substrate;
wherein the viscosity of the ink is in a range of 51 cP to 200 cP (ink temperature: 23° C.) at the shear rate of 100/second,
the flexographic plate on the printing cylinder is made of an elastic material, and
the printing cylinder rotates on the substrate at a rotational speed of 20 rpm or higher when the printing cylinder moves in a rotating manner on the substrate.

12. A method for forming an organic light emitting device which includes electrodes facing each other and a light emitting element layer, the light emitting element layer being arranged between the electrodes and having at least a light emitting layer, comprising the steps of:
preparing a substrate;
forming on the substrate a first electrode layer having a desired pattern;
forming, on the substrate, an insulating layer that has a plurality of openings formed such that desired portions of the first electrode layer are exposed upward;
forming a hole injection layer in the openings and on the insulating layer;
forming a light emitting layer above portions of the hole injection layer using a flexographic printing method, the portions of the hole injection layer being located in the openings; and
forming a second electrode layer such that the second electrode layer is connected to portions of the light emitting layer, the portions of the light emitting layer being located in desired regions of the openings;
wherein the hole injection layer is formed in such a manner that the hole injection layer covers all the openings using a gravure printing method or a gravure offset printing method, and
wherein the step of forming the light emitting layer using a flexographic printing method comprises the steps of placing the substrate on a surface plate that is fixed to and located on a frame, supplying ink containing at least an organic light emitting material onto a flat anilox plate that is fixed to and located on the frame, the anilox plate having a plurality of cells formed on an upper surface of the anilox plate, moving a printing cylinder on the anilox plate so that a flexographic plate provided on the printing cylinder receives the ink from the cells on the anilox plate, and moving the printing cylinder on the substrate located on the surface plate so that the received ink is transferred from the flexographic plate on the printing cylinder onto the substrate,
wherein the viscosity of the ink is in a range of 51 cP to 200 cP (ink temperature: 23° C.) at the shear rate of the ink is 100/second,
the flexographic plate on the printing cylinder is made of an elastic material, and
the printing cylinder rotates on the substrate at a rotational speed of 20 rpm or higher when the printing cylinder moves in a rotating manner on the substrate.

13. The method according to claim 12, further comprising the step of forming a hole transport layer between the hole injection layer and the light emitting layer such that the hole transport layer covers all the openings using a gravure printing method or a gravure offset printing method.

14. An organic light emitting device comprising:
a substrate;
a first electrode layer formed on the substrate, the first electrode layer having a desired pattern;
an insulating layer formed on the substrate, the insulating layer having a plurality of openings formed such that desired portions of the first electrode layer are exposed upward;
a light emitting element layer formed in the openings so as to cover the first electrode layer located in the openings, the light emitting element layer including at least a light emitting layer and a hole injection layer; and
a second electrode layer formed to be connected to portions of the light emitting layer in the light emitting element layer, the portions of the light emitting layer being located in desired regions of the openings;
wherein the light emitting layer provided in the light emitting element layer is formed by using a flexographic printing method,
wherein the flexographic printing method comprises the steps of placing the substrate on a surface plate that is fixed to and located on a frame, supplying ink containing at least an organic light emitting material onto a flat anilox plate that is fixed to and located on the frame, the anilox plate having a plurality of cells formed on an upper surface of the anilox plate, moving a printing cylinder on the anilox plate so that a flexographic plate provided on the printing cylinder receives the ink from the cells on the anilox plate, and moving the printing cylinder on the substrate located on the surface plate so that the received ink is transferred from the flexographic plate on the printing cylinder onto the substrate,
wherein the viscosity of the ink is in a range of 51 cP to 200 cP (ink temperature: 23° C.) at the shear rate of the ink is 100/second,
the flexographic plate on the printing cylinder is made of an elastic material, and
the printing cylinder rotates on the substrate at a rotational speed of 20 rpm or higher when the printing cylinder moves in a rotating manner on the substrate.

15. The organic light emitting device according to claim 14,
wherein the substrate is a transparent substrate, and
the first electrode layer is a transparent electrode layer.

16. The organic light emitting device according to claim 14,
wherein the light emitting layer of the light emitting element layer has a thickness of 70 nm or larger.

17. The organic light emitting device according to claim 14,
wherein the light emitting element layer includes the hole injection layer, the light emitting layer and an electron injection layer, which are arranged in the openings provided in the insulating layer, and
the hole injection layer, the light emitting layer and the electron injection layer are stacked in order of the hole injection layer, the light emitting layer and the electron injection layer.

18. The organic light emitting device according to claim 14,
wherein the light emitting element layer includes the hole injection layer, a hole transport layer, the light emitting layer and an electron injection layer, which are arranged in the openings provided in the insulating layer, and
the hole injection layer, the hole transport layer, the light emitting layer and the electron injection layer are stacked in order of the hole injection layer, the hole transport layer, the light emitting layer and the electron injection layer.

19. The organic light emitting device according to claim 14,
wherein the device is of passive matrix type.

20. The organic light emitting device according to claim 14,
wherein the device is of active matrix type.

21. The organic light emitting device according to claim 14,
wherein the device is an organic light emitting poster, the organic light emitting poster including the insulating layer that is provided with the openings having the maximum width of 10 mm or larger.

22. The organic light emitting device according to claim 14, further comprising a color filter layer.

23. The organic light emitting device according to claim 22, further comprising a color conversion phosphor layer that is arranged between the color filter layer and the first electrode layer.

24. The organic light emitting device according to claim 14,
wherein the light emitting element layer emits light of a desired color including white or emits light of a plurality of desired colors combined in a predetermined pattern.

25. The organic light emitting device according to claim 23,
wherein the light emitting element layer emits blue light, and the color conversion phosphor layer includes a green light conversion layer and a red light conversion layer, the green light conversion layer converting the blue light into green fluorescent light and emitting the green fluorescent light, the red light conversion layer converting the blue light into red fluorescent light and emitting the red fluorescent light.

26. The organic light emitting device according to claim 14,
wherein the hole injection layer and the light emitting layer are formed such that after a film for the hole injection layer is formed, a film for the light emitting layer is formed within one minute after the coating of the film for the hole injection layer, and the hole injection layer and the light emitting layer are simultaneously dried at a temperature of 100° C. to 200° C.
